(19) United States
(12) Patent Application Publication
(10) Pub. No.: US 2022/0107451 A1
(43) Pub. Date: Apr. 7, 2022

(54) INTERFERENCE LAYER SYSTEM WITHOUT A CARRIER SUBSTRATE, METHOD FOR PRODUCING SAME, AND USE THEREOF

(71) Applicant: Carl Zeiss Vision International GmbH, Aalen (DE)

(72) Inventor: Bernhard von Blanckenhagen, Aalen (DE)

(21) Appl. No.: 17/406,293

(22) Filed: Aug. 19, 2021

Related U.S. Application Data
(63) Continuation of application No. PCT/EP2020/054698, filed on Feb. 21, 2020.

(30) Foreign Application Priority Data
Feb. 22, 2019 (EP) 19158947.2

(51) Int. Cl. G02B 5/28; C23C 14/00; C23C 14/02; C23C 14/08; C23C 14/10; C23C 14/30; C23C 28/00; C23C 28/04

(52) U.S. Cl. CPC G02B 5/285; C23C 14/0031; C23C 14/022; C23C 14/024; C23C 14/083; C23C 28/04; C23C 14/10; C23C 14/30; C23C 28/42; C23C 28/44; C23C 14/0005

(57) ABSTRACT

An interference layer system includes a plurality of optically transparent layers. The interference layer system has no carrier substrate and the optically transparent layers are disposed extensively over one another. The optically transparent layers are selected from the group consisting of dielectrics, metals, and combinations thereof, with at least one first optically transparent layer having a refractive index n₁ and at least one second optically transparent layer having a refractive index n₂, and with the first refractive index n₁ and the second refractive index n₂ differing by at least 0.1. The disclosure further relates to the production and the use of the interference layer system.

### CROSS REFERENCE TO RELATED APPLICATIONS

This application is a continuation application of international patent application PCT/EP2020/054698, filed Feb. 21, 2020, designating the United States and claiming priority from European patent application EP 19158947.2, filed Feb. 22, 2019, and the entire content of both applications is incorporated herein by reference.

### TECHNICAL FIELD

The present disclosure relates to an interference layer system which comprises a plurality of optically transparent layers. The present disclosure further relates to a method for producing an interference layer system of this kind, and also to the use thereof.

### BACKGROUND

Optical interference layer systems have been known for a long time and are employed for a wide variety of different purposes. Common to all optical interference layer systems is that layers are employed with a thickness in the order of magnitude of the wavelength of light. Layer thicknesses differ according to whether an optical interference layer system is designed for short wavelengths, such as the UV spectral range, or for longer wavelengths, such as the infrared (IR) spectral range, for example. Optical interference layer systems consist of stacks of layers having different refractive indices. According to the objective, layer stacks feature different numbers of individual layers, different numbers of different layer materials, and different layer thicknesses.

On the basis of the physical laws governing optical interference layers, the optical properties of surfaces for the light can be modified in a defined way to allow specific technical requirements to be realized. An example is the reduction in reflectivity of a surface, with this kind of application of an interference layer system being referred to also as an antireflection layer.

In the visible spectral range, i.e., from about 380 nm to about 780 nm, for example, the reflection of a glass having a refractive index of n=1.5 is about 4%.

By application of an interference layer system designed as an antireflection layer, the reflection can be reduced to values below 1% in the visible spectral range. Antireflection layers of this kind are widely employed in optical systems, for which every lens surface receives an antireflection layer of this kind. Antireflection layers are used on spectacle lenses as well, as is known from EP 2 437 084 A1.

In addition to antireflection utilities, suitably designed interference layer systems are also widely used for applications for enhancing reflection, such as in mirror layer systems; in wavelength filtering, such as in color filters; in the division of a stream of light into 2 polarized fractions, such as in polarization beam splitters; in the division of wavelength ranges, such as in long-pass or short-pass filters; and also in the generation of defined phase shifts. Common to all these applications is that the interference layer system is applied to a substrate. Besides the pure carrier function of the substrate for the interference layer system, many substrates also contribute to the optical imaging of an optical system, by acting, for example, as lenses, imaging mirrors, beam splitter plates or beam splitter cubes. In terms of the mode of action, these substrates are not a constituent of the optical interference layer system, since these substrates are typically thicker than the coherence length of the light employed. The coherence length of light, expressed generally, is the length over which electromagnetic waves are capable of interference. If a layer or a substrate is thicker than this length, this layer or the substrate makes no contribution to the optical interference.

There is a need for optical filters that are able to filter out or reflect selectively defined wavelength ranges from irradiated light, such as sunlight, for example. There is also a need for optical filters which are selectively adjustable in terms of the spectral range to be filtered or reflected, such filters having, for example, not only a reflector effect for the UV-A fraction of the sunlight but also a filter effect into the blue spectral range of visible light, or, for example, a selective filter effect for the IR fraction of sunlight. There is additionally a need for filters whose dimensions can easily be reduced. It is desirable in particular for such a filter to be able to be used in an application medium after comminution, for example, and to be benign to humans and the environment.

For application in an application medium such as in a paint or in a printing ink, EP 0 950 693 A1 discloses interference layer systems in the form of pearlescent pigments, which have an internal, centrally disposed carrier substrate and which evoke a color impression in a viewer.

In the case of the pearlescent pigments known from EP 0 950 693 A1, high-index and low-index layers are applied wet-chemically and enveloping to a substrate platelet, examples being SiO₂ platelets, etc. The pearlescent pigments generally generate a perceived color which is angle-dependent for the viewer. Therefore, typically, in the case of pearlescent pigments, the system comprises a layer construction on the top side and the bottom side of the substrate platelet, this layer construction being symmetrical to the substrate platelet, with the high-index and low-index layers being closed in the edge regions because of the enveloping. The outermost layer envelops the next-inner layer, which in turn envelops the next-inner layer, etc. In the case of the application described in EP 0 950 693 A1, however, a disadvantage is that the possibilities for adjusting the spectral characteristics are limited, because, for example, only a narrowly restricted number of layers can be deposited during the production of these pigments.

EP 1 270 683 A2 relates to a multilayer optical system based on a metal substrate, to which at least one colorless dielectric layer having a refractive index n≤1.8 and a colorless dielectric layer having a refractive index n>1.8 are applied, along with a selectively or nonselectively absorbing layer.

DE 41 24 937 A1 discloses an interference layer system having dielectric and/or metallic layers, with the layer system comprising a layer retainer in the edge zone.

US 2002/0171936 A1 relates to a multilayer interference filter wherein a central region of the filter is substantially stress-free and unsupported. The filter has a frame surrounding the central region.

US 2004/0070833 A1 relates to a Fabry-Perot filter in which a multilayer system is disposed between a first reflector and a second reflector.

In relation to the known prior art, there is a need for the provision of a filter system having improved filter properties.

### SUMMARY

It is an object of the disclosure to provide an interference layer system comprising a plurality of optically transparent layers, where the interference layer system has no carrier substrate and where the optically transparent layers are disposed extensively over one another, where the optically transparent layers are selected from the group consisting of dielectrics, metals and combinations thereof, with at least one first optically transparent layer having a refractive index n₁ and at least one second optically transparent layer having a refractive index n₂, and with the first refractive index n₁ and the second refractive index n₂ differing by at least 0.1.

The object on which the disclosure is based is also achieved through provision of an interference layer system containing a plurality of optically transparent layers, which has no carrier substrate. Exemplary embodiments are specified below.

In accordance with the disclosure the reflection curve of the interference layer system in a wavelength range from 300 nm to 800 nm has at least two regions of different reflection. In the designing of the interference layer system, these at least two regions of different reflection can be selected or adjusted in a defined way within the wavelength range from 300 nm to 800 nm. The present disclosure therefore allows the provision of an interference layer system wherein the at least two wavelength ranges of different reflection can be freely selected and/or tailored to requirement in a wavelength curve from 300 nm to 800 nm.

“Optically transparent layer” or “optically transparent layers” is understood in the sense of the disclosure to mean that the layer or layers absorbs or absorb substantially no light in the visible spectral range, typically no light in the visible spectral range, and/or substantially no radiation in the IR range, typically no radiation in the IR range. “Substantially no absorption” is understood to mean little absorption. The optically transparent layer or layers is or are typically transparent for light in the visible spectral range or for radiation in the IR range. The optically transparent layer or layers is or are typically transparent substantially only for light in the visible spectral range. The optically transparent layer or layers is or are typically transparent substantially only for radiation in the IR range. “Optically transparent layer” or “optically transparent layers” is understood in the sense of the disclosure, more typically according to one exemplary embodiment of the disclosure, to mean that the materials of which the layer or layers is or are composed have typically only little absorption, more typically no absorption, in the visible spectral range.

The visible spectral range covers a wavelength range from 380 nm to 780 nm.

The IR range (IR: infrared radiation) covers in the sense of the disclosure near IR in a wavelength range from 800 nm to 1100 nm.

The UV-A range (UV: ultraviolet radiation) covers in the sense of the disclosure a wavelength range from 315 nm to 400 nm.

“Transparent” for an individual layer is understood in the sense of the disclosure to mean that at least 20% of the visible light or IR radiation incident on an optically transparent layer passes through the layer. The transparency of a layer is typically in a range from 25% to 100%, more typically from 30% to 98%, more typically from 40% to 95%, more typically from 45% to 90%, more typically from 50% to 85%, more typically from 55% to 80%, more typically from 60% to 75%.

Where two or more optically transparent layers are disposed one over another in a layer package, the transmission is determined by the interference effects. Over the spectral profile, therefore, there may be wavelength ranges with high transmission and wavelength ranges with low transmission. A layer package consisting of the two or more optically transparent layers typically has a transmission of more than 20%, typically in a desired wavelength range. The transmission of the overall layer package is typically in a range from 25% to 100%, more typically from 30% to 98%, more typically from 40% to 95%, more typically from 45% to 90%, more typically from 50% to 85%, more typically from 55% to 80%, more typically from 60% to 75%, in each case in a desired wavelength range.

In terms of the optical properties, the optical properties of the materials of which the layers are composed are defined typically by the refractive index n and more typically by the absorption index k. In the spectral range determined by the particular application, optically transparent layer materials typically have an absorption index k<0.008, more typically k<0.005, more typically k<0.003, more typically k<0.001. The absorption index is also referred to as the extinction coefficient or as the imaginary part of the complex refractive index.

In the sense of the disclosure, the data reported for the refractive indices n₁ and n₂ and for the absorption index k are based consistently on the respective refractive index or absorption index measured at a wavelength of 550 nm.

The classic refractive index, also called optical density, is a physical optical property. The classic refractive index is the ratio of the wavelength of light in a vacuum to the wavelength in the material. The refractive index is dimensionless and is dependent generally on the frequency of the light.

The complex refractive index is composed of a real part nᵣ, i.e., the classic refractive index, and an imaginary part k, together in accordance with formula (I):

n=nᵣ−ik (I)

The complex refractive index describes both the temporal and the spatial progression of the wave and also its absorption. The real-value component nᵣ, which is usually greater than 1, shortens the wavelength in the medium. The complex-value component attenuates the wave.

An interference layer system in the sense of the disclosure refers to an arrangement of plural optically transparent layers in which there is constructive and destructive interference of irradiated light because of phenomena of reflection and transmission at the individual optically transparent layers. Plural optically transparent layers are understood to mean at least 2, typically at least 4, more typically at least 6, more typically at least 8, more typically at least 10, more typically at least 12, more typically at least 14, more typically at least 16, very typically at least 18, and especially typically at least 20 optically transparent layers. Where the absorption index k of at least one optically transparent layer is k>0, typically k≥0.008, a part is also played by the absorption of incident light. In this case the transmission is reduced by absorption. According to one preferred exemplary embodiment, the interference layer system of the disclosure consists exclusively of this arrangement of plural optically transparent layers in which there is constructive and destructive interference of irradiated light because of phenomena of reflection and transmission at the individual optically transparent layers. In accordance with the disclosure the interference layer system comprises a stack of optically transparent layers for generating optical interference. In light of these phenomena of reflection and transmission at the various layers of the interference layer system, there is a reduction in the intensity of the transmitted light in defined wavelength ranges, typically an extinction of wavelength ranges or destructive interference, thereby generating an optical filter effect. The interference layer system in the sense of the disclosure may also be termed an interference filter.

The interference layer system of the present disclosure has no carrier substrate. The interference layer system of the disclosure therefore contains no platelet-shaped substrates, such as, for example, glass platelets, SiO₂ platelets, Al₂O₃ platelets, natural or synthetic mica platelets, etc. Nor is the interference layer system of the disclosure disposed on a spectacle lens, an optical lens substrate, a glass disk, a polymeric foil or a polymeric plate, etc.

According to one exemplary embodiment of the disclosure, the interference layer system may also act as a UV-A reflector (UV: ultraviolet light), with the UV-A light being reflected.

According to a further exemplary embodiment of the disclosure, the interference layer system may have a filter effect for a wavelength range from 360 nm to 450 nm.

According to a further exemplary embodiment of the disclosure, the interference layer system may have a filter effect for certain wavelength ranges of visible light, as specified below in Table 1.

TABLE 1

| Color | Wavelength range [nm] |
|---|---|
| Violet | 380-450 |
| Blue | 450-482 |
| Greenish blue | 482-487 |
| Cyan (Blue) | 487-492 |
| Blueish green | 492-497 |
| Green | 497-530 |
| Yellowish green | 530-560 |
| Yellow-green | 560-570 |
| Greenish yellow | 570-575 |
| Yellow | 575-580 |
| Yellowish orange | 580-585 |
| Orange | 585-595 |
| Reddish orange | 595-620 |
| Red | 620-780 |

According to a further exemplary embodiment of the disclosure, the interference layer system may be designed as a heat reflection filter, typically in the near infrared range. This near infrared (IR) is divided into IR-A, in a range from 780 nm to 1.4 μm, and into IR-B, in a range from 1.4 μm to 3 μm. The interference layer system of the disclosure typically has a filter effect in the IR-A range.

According to a further preferred exemplary embodiment, the interference layer system of the disclosure is a heat reflection filter for a wavelength range from 800 to 850 nm.

According to a further preferred exemplary embodiment, the interference layer system of the disclosure is a heat reflection filter for a wavelength range from 850 to 900 nm.

According to a further preferred exemplary embodiment, the interference layer system of the disclosure is a heat reflection filter for a wavelength range from 870 to 950 nm.

According to a further preferred exemplary embodiment, the interference layer system of the disclosure is a heat reflection filter for a wavelength range from 1000 to 1100 nm.

The filter properties of the interference layer system of the disclosure may be adjusted through selection of the materials of which the individual layers of the interference layer system consist, their layer thickness and/or the number of layers and/or their layer sequence. The interference layer system of the disclosure may have, for example, defined values for the reflection, the transmission and/or the absorption, for the light incident on the interference layer system. The filter properties of the interference layer system of the disclosure may also be present at defined incident angles of the incident light. If the incident angle is other than 0°, the filter properties may also relate to the polarized fractions of the incident light. An angle of 0° refers to the case where the beam of light impinges vertically onto the surface. Where the incident angle differs from 0°, the incident angle is measured relative to the perpendicular to this surface.

The interference layer system of the disclosure, which has no carrier substrate, may be selected and provided advantageously in relation to defined filter properties, which are selected and provided typically from the group consisting of reflection, transmission, absorption, spectral light filtering in a desired wavelength range, and combinations thereof.

The interference layer system according to the present disclosure is produced typically by vapor deposition, typically by means of physical vapor deposition (PVD). It is also possible for the individual layers to be generated by chemical vapor deposition (CVD) or by sputtering. According to one preferred exemplary embodiment of the disclosure, the individual layers are applied by means of PVD.

Accordingly, the interference layer system of the present disclosure may also be designated as an interference layer system generated by vapor deposition, for example a PVD interference layer system or CVD interference layer system. The interference layer system of the disclosure is typically not produced wet-chemically, by precipitation, for example, of the individual layers one atop another and in succession in a liquid phase. According to one preferred exemplary embodiment of the disclosure, the interference layer system of the disclosure is a PVD interference layer system.

The interference layer system or the interference filter of the present disclosure here may have a film-like or foil-like configuration. In this case the interference layer system may also be termed an interference layer film or an interference layer foil.

The interference layer system may also have a particulate configuration. The particulate interference layer system has a constant thickness over the entire area, with a maximum deviation of ±10%, typically ±5%, more typically ±2%, based in each case on the overall layer thickness of the stack of the individual layers applied over one another. The interference layer particles of the disclosure have a planar surface. Since the particulate interference layer system is generated by comminution from the interference layer film or interference layer foil, it typically has at least partly straight fracture edges. This is clearly visible from scanning electron micrographs of the particulate interference layer system.

In a further exemplary embodiment, the interference layer system of the present disclosure may also be designated as a UV-A reflector or UV-A interference filter. Accordingly, the interference layer film may also be designated as a UV-A interference filter film, or the interference layer foil may also be designated as a UV-A interference filter foil. The interference layer particles may also be designated as UV-A interference filter particles or UV-A reflector particles.

According to one preferred development of the disclosure, the interference layer system of the disclosure may have not only a reflector effect in the UV-A range but also a filter effect in the violet and/or blue light range of visible light. According to a further preferred exemplary embodiment of the disclosure, the interference layer system of the disclosure reduces the transmission in the range from 360 nm to 450 nm. According to a further preferred exemplary embodiment of the disclosure, the interference layer system of the disclosure reduces the transmission in the range from 360 nm to 450 nm by at least 80%. If in this exemplary embodiment the absorption index k of all the layers of the interference layer system is 0, 80% of the incident light is reflected. In practice, a virtually 80% reflection is also achieved when the absorption index k of all the layers of the interference layer system is k<0.003.

In a further exemplary embodiment, the interference layer system of the present disclosure may also be designated as a short-pass interference filter. Accordingly, the interference layer film may also be referred to as a short-pass interference filter film, or the interference layer foil may also be referred to as a short-pass interference filter foil. The interference layer particles may also be referred to as short-pass interference filter particles. A short-pass interference filter typically has a high transmittance for short wavelengths and a low transmittance for long wavelengths. Short wavelengths in this context are typically in a range from 380 nm to 780 nm, more typically from 420 nm to 800 nm. An example of a short-pass interference filter is an IR filter which has little transmission in the IR range, but high transmission in the visible range.

In a further exemplary embodiment, the interference layer system of the present disclosure may also be referred to as a long-pass interference filter. Accordingly, the interference layer film may also be referred to as a long-pass interference filter film, or the interference layer foil may also be referred to as a long-pass interference filter foil. The interference layer particles may also be referred to as long-pass interference filter particles. A long-pass interference filter typically has a high transmittance for long wavelengths and a low transmittance for short wavelengths. Long wavelengths in this context are typically in a range from 420 nm to 780 nm, more typically from 450 nm to 800 nm. An example of a long-pass interference filter is a UV reflector/violet filter which transmits visible light.

In a further exemplary embodiment, the interference layer system of the present disclosure may also be referred to as a band-pass interference filter. Accordingly, the interference layer film may also be referred to as a band-pass interference filter film, or the interference layer foil may also be referred to as a band-pass interference filter foil. The interference layer particles may also be referred to as band-pass interference filter particles. A band-pass filter typically has a high transmittance for a defined wavelength band, while shorter and longer wavelengths are reflected or absorbed. A transmitted wavelength band of this kind may lie, for example, in a range from 500 nm to 600 nm, and also, for example, in a range from 540 nm to 580 nm. The transmitted wavelength range may alternatively relate to a different wavelength band.

In a further exemplary embodiment, the interference layer system of the present disclosure may also be referred to as a band-stop interference filter. Accordingly, the interference layer film may also be referred to as a band-stop interference filter film, or the interference layer foil may also be referred to as a band-stop interference filter foil. The interference layer particles may also be referred to as band-stop interference filter particles. A band-stop filter typically has a low transmittance for a defined wavelength range, whereas shorter and longer wavelengths are transmitted. A wavelength range of this kind with low transmission may lie, for example, in a range from 500 nm to 600 nm, and also, for example, from 540 nm to 580 nm. The wavelength range with low transmission may alternatively relate to a different wavelength range.

In a further exemplary embodiment, the interference layer system of the present disclosure may also be referred to as an IR interference filter. Accordingly, the interference layer film may also be referred to as an IR interference filter film, or the interference layer foil may also be referred to as an IR interference filter foil. The interference layer particles may also be referred to as IR interference filter particles. An IR interference filter typically has a low transmittance for IR radiation in the range of 800 nm to 1100 nm, typically from 850 nm to 1000 nm.

Where the interference layer system of the disclosure is used in an application medium, such as a coating material, for example, there is typically no substantial color change or color generation perceptible to a viewer, typically no color change or color generation affecting the application medium, the coating material for example, insofar as the interference layer system is designed as a reflector for the UV-A spectral range. The typically largely colorless or neutral, more typically colorless or neutral, impression allows the interference layer system of the disclosure to be used as an optical filter and/or, for example, as a reflector for UV-A light in an application medium, a coating material for example, without any substantial change to the color of the application medium—the coating material, for example. Following application of the coating material, the substrate is likewise not substantially altered, and typically not altered, optically by the interference layer system of the disclosure.

When the interference layer system of the disclosure is used in an application medium, such as a coating material, for example, there is likewise no color change or color generation affecting the application medium, the coating material for example, insofar as the interference layer system is designed as a filter or reflector for the IR spectral range.

Insofar as the interference layer system of the disclosure is to be used as a colorant, it may also impart a coloration—for example, blue, green, yellow, red or combinations thereof—to an application medium, such as a coating material, for example, as for example a paint or ink, including printing ink.

It is an object of the disclosure to provide an interference layer system with a plurality of optically transparent layers, which includes no carrier substrate. Typically, the system additionally has a reflector and/or filter effect in the UV-A light range and typically also in the wavelength range from 380 nm to 430 nm as well, so that the transmission of the UV-A light through the interference layer system, and typically additionally in the wavelength range from 380 nm to 430 nm as well, is reduced by more than 25%, more particularly by more than 50%, and even more particularly by more than 60%, based in each case on the transmission without the filter effect.

In order to optimize the filter effect, the layer thicknesses of the plurality of optically transparent layers in the interference layer system and/or the number of layers may be adjusted with respect to one another as a function of the respective refractive index and in relation to the wavelength range that is to be reflected and/or filtered out.

It is essential to the disclosure that the interference layer system has no carrier substrate. A carrier substrate in the sense of the disclosure refers to a substrate on which the optically transparent layers are applied, with the substrate typically having greater mechanical stability than the optically transparent layers.

According to one preferred development of the disclosure, the interference layer system of the disclosure is composed exclusively of layers of dielectrics, typically exclusively of metal oxide layers. In this exemplary embodiment the interference layer system of the disclosure typically comprises no purely metallic layers and/or layers containing elemental metal.

According to another preferred exemplary embodiment of the disclosure, the interference layer system may comprise at least one optically semitransparent metal layer. The interference layer system of the disclosure may in this case be composed exclusively of a plurality of semitransparent metal layers. The metals involved may be silver, gold, aluminum, chromium, titanium, iron, or alloys, or mixtures thereof. A metal layer is generally semitransparent if the layer thickness is less than 40 nm. In the interference layer system of the disclosure, a metal layer typically has a thickness in a range from 5 nm to 38 nm, more typically from 8 nm to 35 nm, more typically still from 10 nm to 30 nm, more typically still from 15 nm to 25 nm.

According to a further exemplary embodiment of the disclosure, the interference layer system comprises not only layers consisting of dielectrics, typically metal oxide(s), but also layers consisting of metal(s). For example, an interference layer system of the disclosure may consist substantially of layers of dielectrics, typically layers of metal oxide(s), and may additionally comprise, for example, one, two or three layers of metal(s).

According to a further exemplary embodiment of the disclosure, the interference layer system may also comprise semitransparent layers having an absorption index k>0.001, typically k>0.003, typically k>0.005, more typically k>0.008, for example k>0.01. The layers in this case may comprise, for example, metal oxides at wavelengths shorter than the wavelength of the absorption edge.

Characteristics of the interference layer system of the present disclosure include the absence of a carrier substrate for the optically transparent layers. The inventors have determined that, if the optically transparent layers as such are disposed extensively over one another and typically directly extensively bordering one another, the resulting interference layer system has surprising mechanical stability and in particular is amenable to handling.

The interference layer system of the present disclosure here may take the form of a film or a foil, or else a particulate form. With preference the interference layer system of the disclosure consists exclusively of the optically transparent layers disposed extensively over one another, with these layers each consisting substantially, typically entirely, of a dielectric material or two or more dielectric materials, typically a metal oxide or two or more metal oxides.

The interference layer system may thus be film-like or foil-like with a size of several square centimeters. For example, the interference layer system may have an area of 1 cm² to 400 cm², typically of 2 cm² to 250 cm², more typically of 4 cm² to 150 cm².

According to another preferred exemplary embodiment of the disclosure, the interference layer system of the disclosure may also be provided with one or more further surface layers, i.e., surface layers disposed externally on the layer stack of optically transparent layers, these one or more surface layers having no optical functions but instead improving the properties in use. For example, the interference layer system of the disclosure may have a water repellency layer, in order, for example, to counteract possible soiling. Also possible, for example, is for interference layer particles to have undergone surface chemical modification, in order to counteract aggregation or sedimentation, in an application medium such as a coating material, for example.

The interference layer system in this case may have flexibility, allowing the film or the foil to be rolled up.

Notwithstanding the flexibility of the interference layer system, it can easily be comminuted with exposure to mechanical forces. Accordingly, with exposure to mechanical forces, the interference layer system provided in film or foil form can be comminuted to provide interference layer particles or interference filter particles. These particles may have an area of 1 μm² to 1 cm², typically 5 μm² to 40,000 μm², more typically of 10 μm² to 10,000 μm², more typically of 100 μm² to 5,000 μm².

Exemplary embodiments of the interference layer system of the disclosure are specified below.

It is another object on which the disclosure is based to provide a method for producing an interference layer system, the method comprising the following steps:
(a) providing an extensive carrier substrate material,
(b) applying a release layer,
(c) applying a plurality of optically transparent layers, to generate an interference layer system, and
(d) detaching the interference layer system from the extensive carrier substrate material.

Exemplary embodiments of the method of the disclosure are specified below.

According to an exemplary embodiment of the method of the disclosure, the extensive carrier substrate has a low surface roughness, typically a surface roughness of <3 nm rms, more typically of <2 nm rms, and even more typically of <1 nm rms.

By “rms” is meant the root-mean-squared roughness, also identified as R_{q}. The root-mean-squared roughness rms or R_{q} represents the standard deviation of the distribution of the surface heights, as elucidated in E. S. Gadelmawla et al., “Roughness parameters,” Journal of Materials Processing Technology 123 (2002) 133-145, section 2.2, the disclosure content for which is hereby incorporated by reference. Mathematically, the root-mean-squared roughness R_{q} is defined as specified in formula (II):

$${R}_{q} = \sqrt{\frac{1}{l} {\int }_{0}^{l} {\{ y ( x ) \}}^{2} dx} , \qquad ( II )$$

wherein: “l” is the measurement length,
   “y” is the surface height, and
   the length “x” goes from 0 to “l.”

Furthermore, it is an object of the disclosure to provide an optical filter which is or includes an interference layer system containing a plurality of optically transparent layers, which has no carrier substrate. This optical filter may be a UV reflector, color filter, heat reflection filter or IR filter and/or antireflection filter.

Lastly, it is another object on which the disclosure is based to provide an application medium which contains an interference layer system containing a plurality of optically transparent layers, which has no carrier substrate.

According to an exemplary embodiment of the disclosure, the application medium is selected from the group consisting of glazes, glasses, plastics, and coating materials, typically paints, varnishes, and printing inks.

According to another exemplary embodiment of the disclosure, the application medium is a coating material.

One of the features of the interference layer system of the disclosure is that it has no carrier substrate.

In the interference layer system of the present disclosure, the optically transparent layers are disposed extensively over one another and typically bordering one another. “Disposed bordering one another” means in the sense of the disclosure that adjacent layers are disposed directly, i.e., in extensive contact with one another. The optically transparent layers here are typically stacked so as to be flush in the edge regions. Accordingly, in the interference layer system of the disclosure, the edge regions, i.e., viewed “from the side,” typically contain “open layer ends,” i.e., unenveloped layer ends.

In accordance with the disclosure the optically transparent layers are not applied enveloping. It is instead preferred for the optically transparent layers to be defined layer stacks of layers each with defined layer thickness across the whole width of the interference layer system. With this disposition of the optically transparent layers, the identical and defined layer sequence with respectively defined layer thickness is present in the edge regions as well as in the middle region of the interference layer system. There is typically no envelopment of the edge regions of the optical transparent layers in the layer stack.

According to one preferred exemplary embodiment, the layer thickness of each optically transparent layer is in a thickness range from 5 nm to 500 nm, typically 6 nm to 460 nm, typically 7 nm to 420 nm, typically 8 nm to 380 nm, typically 9 nm to 320 nm, typically 10 nm to 280 nm, typically 11 nm to 220 nm, typically 12 nm to 180 nm, typically 13 nm to 150 nm, typically from 14 nm to 120 nm, more typically from 15 nm to 110 nm, more typically from 25 nm to 90 nm, more typically still from 30 nm to 80 nm. The thickness of each layer here represents the spatial extent of the layer perpendicular to the surface.

In terms of the layer sequence, the interference layer system according to the present disclosure may have a symmetrical or an asymmetric layer construction.

An asymmetric layer construction may come about, for example, from the layer thickness of the layers disposed in the layer stack being different from one another according to disposition in the layer stack. An asymmetric layer construction may also come about from the metal oxides used in the individual layers being different from one another, so that the resulting construction is not symmetrical.

An asymmetric layer construction may also come about from the two outer layers on the top side and bottom side, respectively, of the interference layer system being different from one another. For example, in the case of an alternating disposition of high-index layers, TiO₂ layers for example, and low-index layers, SiO₂ for example, the bottom face of the interference layer system may take the form of an SiO₂ layer, and the upper face of the interference layer system may take the form of a TiO₂ layer.

In the interference layer system of the disclosure, none of the optically transparent layers has the function of a carrier substrate. Surprisingly, the mechanical stability of the interference layer system of the disclosure comes about as a result of the plurality of optically transparent layers which, each considered separately, typically do not have sufficient mechanical stability. The inventors have surprisingly found that the interference layer system has sufficient mechanical stabilization when just at least 4, typically at least 6, more typically at least 8, more typically at least 10, more typically at least 12, more typically at least 14 optically transparent layers are disposed over one another.

The interference layer system of the disclosure is an extensive structure typically having an overall thickness from a range from 40 nm to 5 μm, typically from 80 nm to 4 μm, more typically from 140 nm to 3 μm, more typically still from 260 nm to 2.5 μm, more typically still from 400 nm to 2 μm, more typically still from 600 nm to 1.5 μm. Having proven very suitable is a thickness range from 750 nm to 1.3 μm, more typically from 800 nm to 1.2 μm.

According to another preferred exemplary embodiment of the disclosure, the interference layer system comprises 4 to 100, typically 6 to 80, more typically 8 to 70, more typically still 10 to 60, more typically still 12 to 50, more typically still 14 to 40 optically transparent layers, or consists thereof.

By virtue of the good mechanical stability, the interference layer system of the disclosure may take the form of a film or foil, typically an optical film or optical foil, without a carrier substrate. The interference layer system of the disclosure in film or foil form is typically flexible, allowing the interference layer system, according to one exemplary embodiment of the disclosure, to be rolled up or to conform to a substrate.

The interference layer system of the disclosure may therefore take the form of a free interference layer film or free interference layer foil, or free particles. “Free” is understood to mean, in accordance with the disclosure, that the interference layer system of the disclosure is present in unbound form, i.e., without a carrier substrate or detached from a carrier substrate.

The interference layer film of the disclosure or interference layer foil of the disclosure here may have an area of several square centimeters, as for example of 2 to 400 cm², typically of 3 to 200 cm², more typically of 4 to 120 cm², more typically still of 8 to 100 cm².

The layer system of the disclosure, typically in the form of an interference layer film or interference layer foil, has surprisingly good handling qualities. Thus, for example, the interference layer system in the form of an interference layer film or interference layer foil can be used directly as an optical film, in the context of physical investigations, for example, or in complex optical systems, such as disposed in mounts, for example.

Alternatively, the interference layer system in film form or foil form can easily be comminuted with exposure to mechanical forces. Thus, for example, the interference layer film of the disclosure or interference layer foil of the disclosure may be comminuted by fluidization in a medium, as for example a gas or a liquid. Exposure to ultrasound as well, for example, allows the interference layer system of the disclosure to be comminuted. As a function of the duration and the input of energy during comminution, a defined size distribution can be established. The interference layer system of the disclosure may thus also be present an average particle diameter, also referred to as average particle size, of for example 1 μm to 500 μm, more typically 2 μm to 400 μm, more typically from 5 μm to 250 μm, more typically still from 10 μm to 170 μm, more typically still from 20 μm to 130 μm, more typically still from 40 μm to 90 μm.

An average particle size refers, in accordance with the disclosure, to the median value D50 of the volume-averaged size, for which 50% of the particles have a size below the specified D50 value and 50% of the particles have a size of above the specified D50 value.

The particle size distribution here may be determined by laser diffractometry, using the CILAS 1064 instrument, for example.

The particles obtained on comminution of the interference layer system have a unitary and hence defined layer construction over the entire area of the particle, including the edge regions. It has surprisingly emerged that following comminution of the interference layer system of the disclosure, the interference layer particles obtained accordingly are mechanically stable and substantially flat. Typically, therefore, the interference layer particles are present substantially not in a rolled-up form. Very typically the interference layer particles of the disclosure are present in a flat form, i.e., not in a rolled-up form.

According to another preferred exemplary embodiment, the optically transparent layers each comprise one or more dielectrics, typically metal oxide(s), in an amount of 95 to 100 wt %, more typically 97 to 99.5 wt %, even more typically 98 to 99 wt %, based in each case on the total weight of the respective optically transparent layer.

Very typically each optically transparent layer consists exclusively of a dielectric, typically metal oxide, or of a plurality of dielectrics, typically metal oxides. According to another preferred exemplary embodiment, each optically transparent layer consists of a single metal oxide.

By “metal oxide(s)” are meant, in the sense of the disclosure, metal oxide hydroxide(s) and metal hydroxide(s) as well, and also mixtures thereof. Typically the metal oxide or metal oxides is or are pure metal oxide(s) without a water fraction.

According to another preferred exemplary embodiment, the interference layer system of the disclosure has at least two low-index optically transparent layers, having a refractive index n₁<1.8, and at least two high-index transparent layers, having a refractive index n₂≥1.8.

According to another preferred exemplary embodiment, the low-index optically transparent layer has a refractive index n₁ from a range from 1.3 to 1.78 and is selected typically from the group consisting of silicon oxide, aluminum oxide, magnesium fluoride, and mixtures thereof. Boron oxide is another possibility for use as low-index metal oxide. According to one preferred exemplary embodiment of the disclosure, the aforesaid low-index metal oxides are x-ray-amorphous.

Silicon oxide typically comprises SiO₂. In the sense of the disclosure, silicon oxide, more particularly SiO₂, is also understood to be a metal oxide. Aluminum oxide typically comprises Al₂O₃ or AlOOH. Boron oxide typically comprises B₂O₃. Magnesium fluoride typically comprises MgF₂.

Very typically the low-index optical transparent layer is selected from the group consisting of silicon oxide, aluminum oxide, magnesium fluoride, and mixtures thereof. With preference the aforesaid low-index metal oxides are x-ray-amorphous. With further preference the silicon oxide takes the form of SiO₂. With further preference the aluminum oxide takes the form of Al₂O₃. With further preference the magnesium fluoride takes the form of MgF₂.

According to another preferred exemplary embodiment, the high-index optically transparent layer has a refractive index n₂ from a range from 2.0 to 2.9 and is selected typically from the group consisting of titanium oxide, iron oxide, niobium oxide, tantalum oxide, zirconium oxide, tin oxide, cerium oxide, chromium oxide, cobalt oxide, and mixtures thereof. According to one preferred exemplary embodiment of the disclosure, the aforesaid high-index metal oxides are x-ray-amorphous.

Titanium oxide typically comprises TiO₂. More typically the TiO₂ is in the form of anatase or rutile, more typically still in the form of rutile. According to a further exemplary embodiment of the disclosure, the TiO₂ is in amorphous form, i.e., typically x-ray-amorphous. The iron oxide is typically in the form of Fe₂O₃ (hematite) or Fe₃O₄ (magnetite), more typically in the form of Fe₂O₃. The niobium oxide is typically in the form of Nb₂O₅. The tantalum oxide is typically in the form of Ta₂O₅. The zirconium oxide is typically in the form of ZrO₂. The tin oxide is typically in the form of SnO₂.

Very typically the high-index layer is selected from the group consisting of rutile, niobium oxide, tantalum oxide, zirconium oxide, and mixtures thereof. With preference the aforesaid high-index metal oxides are x-ray-amorphous. According to a further preferred exemplary embodiment, the titanium oxide is present in the form of TiO₂, typically rutile.

According to one preferred exemplary embodiment of the disclosure, the interference layer system has an alternating layer sequence of two optically transparent layers, with the first optically transparent layer having a refractive index n₁ and the second optical transparent layer having a refractive index n₂, and with n₁ and n₂ differing typically by 0.1 to 1.4, more typically by 0.2 to 1.3, more typically by 0.3 to 1.2, more typically by 0.4 to 1.1, more typically by 0.5 to 1.0, more typically by 0.6 to 0.9.

According to one preferred exemplary embodiment of the disclosure, the interference layer system comprises layers of silicon oxide, typically SiO₂, as low-index layer, and layers of titanium oxide, typically TiO₂, more typically amorphous TiO₂, as high-index layer, with the silicon oxide layers and the titanium oxide layers typically being disposed in alternation. The interference layer system of the disclosure typically comprises a total of 4 to 100, typically 6 to 80, typically 8 to 70, more typically 10 to 60, more typically 12 to 50, titanium oxide layers and silicon oxide layers, or consists thereof. According to one preferred exemplary embodiment the titanium oxide layers and silicon oxide layers are x-ray-amorphous.

Very typically the interference layer system according to the present disclosure consists substantially of metal oxide(s), typically of metal oxide(s). By virtue of the preferred metal-oxidic structure, the interference layer system according to the present disclosure is not susceptible to corrosion. Advantageously, therefore, there is no need for application of separate anticorrosion layers. Accordingly, even in a corrosive environment, in the presence of water and oxygen, for example, the interference layer system of the disclosure is stable with respect to corrosion.

Very advantageously the interference layer system in accordance with the present disclosure is unobjectionable from the standpoints of health and environment, including in terms of the metal oxides occurring in nature.

The disclosure also relates to the use of an interference layer system containing a plurality of optically transparent layers, which has no carrier substrate. This optical filter may take the form of a film or a foil. For example, the interference layer film or interference layer foil may be disposed in a mount.

According to an exemplary embodiment, the present disclosure relates to an application medium, typically a coating material, which comprises an optical interference layer system containing a plurality of optically transparent layers, which has no carrier substrate.

The coating material may comprise varnish, paint or ink, or medical devices.

The application medium may be a glaze, a ceramic or a plastic.

The interference layer system of the present disclosure may be produced by the methods as described herein.

In accordance with the disclosure, an extensive carrier substrate material is provided, which is given a release layer. Applied to this release layer subsequently, in succession, are a plurality of optically transparent layers selected from the group consisting of dielectrics, metals, and combinations thereof, to generate an interference layer system containing a plurality of optically transparent layers, which has no carrier substrate. The interference layer system thus obtained is subsequently detached from the extensive carrier substrate material.

The extensive carrier substrate material may be an inorganic or an organic surface. As inorganic surface it is possible to use, for example, a metallic substrate or a ceramic substrate. As organic surface it is possible to use a surface of plastic. The plastic surface here may be modified, with a coating, for example, such as a polysiloxane-based hardcoat, for example.

In this case the carrier substrate material may be immobile, in the form of a plate substrate, for example, or mobile, in the form of a belt substrate, for example.

According to one preferred exemplary embodiment of the disclosure, the carrier substrate material used is a plastics material of the kind also used in the production of polymeric spectacle lenses.

The carrier substrate material may comprise or consist of a plastics material, with the plastics material being selected from the group consisting of polythiourethane, polyepisulfide, polymethyl methacrylate, polycarbonate, polyallyl diglycol carbonate, polyacrylate, polyurethane, polyurea, polyamide, polysulfone, polyallyl, fumaric acid polymer, polystyrene, polymethyl acrylate, biopolymers, and mixtures thereof. The plastics material typically comprises or consists of a polymer material selected from the group consisting of polythiourethane, polyepisulfide, polymethyl methacrylate, polycarbonate, polyallyl diglycol carbonate, polyacrylate, polyurethane, polyurea, polyamide, polysulfone, polyallyl, fumaric acid polymer, polystyrene, polymethyl acrylate, biopolymers, and mixtures thereof.

Very typically the plastics material is selected from the group consisting of polyurethane, polyurea, polythiourethane, polyepisulfide, polycarbonate, polyallyl diglycol carbonate, and mixtures thereof.

The plastics material used may be the same materials as are also used in the production of polymeric spectacle lenses. Suitable polymer materials are available for example under the tradename MR6, MR7, MR8, MR10, MR20, MR174, CR39, CR330, CR607, CR630, RAV700, RAV7NG, RAV7AT, RAV710, RAV713, RAV720, TRIVEX, PANLITE, MGC 1.76, RAVolution, etc.

The base material of CR39, CR330, CR607, CR630, RAV700, RAV7NG, RAV7AT, RAV710, RAV713 and RAV720 is polyallyl diglycol carbonate. The base material of RAVolution and TRIVEX is polyurea/polyurethane. The base material of MR6, MR7, MR8 and MR10 is polythiourethane. The base material of MR174 and MGC1.76 is polyepisulfide.

These plastics materials known from polymeric spectacle lens production are typically provided with antireflection coats, which, however, are applied permanently on the plastics surface.

According to one preferred exemplary embodiment of the disclosure, the carrier substrate is coated with a coating material, such as a polysiloxane-based hardcoat material, for example. This coating provides protection from mechanical damage, such as from scratches, for example. According to another preferred exemplary embodiment of the disclosure, a primer coat is disposed between the carrier substrate—plastics substrate, for example—and the hardcoat layer, and improves the adhesion of the hardcoat layer to the carrier substrate—plastics substrate, for example.

The hardcoat materials are applied typically by dip-coating methods or spin-coating methods in liquid form on both sides of the substrate and are then cured thermally, for example. Depending on the composition of the coating material, curing may also take place using UV light. The UV light in this case induces chemical reactions which lead to the full curing of the liquid coating material.

These hardcoat materials are typically harder than the plastics substrate. Typically these coating materials have an indentation hardness of greater than 150 MPa, more typically greater than 250 MPa, measured by means of nanoindentation, also referred to as instrumented indentation testing. The instrumented indentation depth here is determined as specified in Oliver W. C. and Pharr, G. M., “Measurement of hardness and elastic modulus by instrumented indentation: Advances in understanding and refinements to methodology,” J. Mater. Res., vol. 19, No. 1, January 2004, pages 3 to 20.

The layer thickness of the fully cured hardcoat layer is typically 1 μm, typically more than 1.5 μm, as for example 2 μm or 3 μm.

In a further exemplary embodiment of the disclosure, a liquid primer coat is first applied typically directly to the plastics substrate by means of dip-coating methods or spin-coating methods. Following thermal drying of this primer coat, it typically has a layer thickness >400 nm, such as from 500 nm to 1 μm, for example. Typically then applied to this primer coat is a hardcoat layer, as described above. The purpose of the primer coat is to improve the adhesion of the hardcoat layer on the plastics substrate.

The primer for the primer coat is selected typically from the group consisting of polyurethane dispersion, polyurethane-polyurea dispersion, and mixtures thereof. For further reference in this respect, reference is made to U.S. Pat. No. 5,316,791, more particularly to column 3, line 41 to column 6, line 11, the content of which is hereby incorporated by reference. One commercially available primer is, for example, the primer PR-1165 from SDC TECHNOLOGIES, INC. 45 Parker, Suite 100 Irvine, Calif. 92618 USA.

The hardcoat material is typically a polysiloxane, obtainable for example by reaction of at least one organosilane and at least one tetraalkoxysilane in the presence of colloidal inorganic oxide, fluoride or oxyfluoride. For further reference in this respect, reference is made to DE 10 2011 083 960 A1, the content of which is hereby incorporated by reference. A commercially available polysiloxane hardcoat material is, for example, MP-1154D from SDC TECHNOLOGIES, INC. 45 Parker, Suite 100 Irvine, Calif. 92618 USA.

In accordance with the disclosure the fully cured hardcoat layer typically has a roughness <3 nm rms, typically <2 nm rms, more typically <1 nm rms.

The roughness of the hardcoat layer may be adjusted through the choice of the solvent—for example, 1 methoxy-2-propanol, ethanol and/or methanol or mixtures thereof—and/or through the use of at least one flow control additive, examples being silicone surfactant(s) or fluorosurfactant(s).

In light of this typically low surface roughness, the subsequently applied release layer and also the interference layer system of the disclosure applied to the release layer take the form typically of smooth layers, which typically have correspondingly low roughnesses. In the case of a smooth release layer and also an interference layer system with smooth layers, the interference layer system of the disclosure can be detached readily from the carrier substrate. Furthermore, smooth layers in the interference layer system of the disclosure result in defined optical properties—defined filter properties, for example.

In the case of the present disclosure, a release layer is applied to the extensive carrier substrate material, this layer enabling detachment or separation of the subsequently applied plurality of metal oxide-containing layers.

Materials of different kinds can be used as the release layer. For example, organic materials soluble in an organic solvent can be applied. As organic release agents it is possible, for example, to use waxes or fats which are soluble, for example, in organic solvent.

In accordance with the disclosure it is preferable to use a water-soluble inorganic salt as the release layer. The use of a water-soluble salt is preferred in relation to workplace safety and the environment.

Inorganic salts used are typically salts of the alkali metals and/or alkaline earth metals. Anions used may be the usual salt-formers, examples being halides, sulfates, phosphates, etc. Halides, more particularly chlorides, are used with preference for anions of the salts. Very typically a release layer of NaCl is used, as an inexpensive salt.

The release layer is applied in a suitable layer thickness to the carrier substrate material. The layer is typically applied to the extensive carrier substrate material with a defined layer thickness by vacuum deposition. The release layer thickness here may be in a range from 10 nm to 100 nm, typically from 20 nm to 50 nm. A release layer thickness of 30 nm, composed of NaCl, for example, has proven very suitable. The release layer may be applied, for example, with an electrode beam evaporator without reactive gas. A defined number of metal oxide-containing layers is then applied to this release layer in succession, and typically immediately one upon another, by vapor deposition.

The number and thickness and also the nature of the metal oxide-containing layers for application are set as a function of the particular end use—for example, the optical filter properties of the interference layer system. The release layer, or plurality of metal oxide-containing layers, are applied using a customary vapor deposition unit, typically a PVD unit (PVD: physical vapor deposition). The further process conditions, such as vacuum vapor deposition rate, inert gas, reactive gas, etc., for example, are adjusted in accordance with manufacturer information and with the desired optical properties of the interference layer system of the disclosure.

Following application of the desired number of metal oxide-containing layers, air is admitted to the coating unit, typically a vacuum coating unit. The substrates are then removed and stored in a water vapor atmosphere, such as in the ambient atmosphere, for example. The relative atmospheric humidity is typically more than 30%.

The release layer—the NaCl layer, for example—absorbs moisture from the ambient atmosphere and so reduces the adhesion between the vapor-deposited interference layer system and the extensive carrier substrate material.

The coating unit used may be, for example, the coating units from Satisloh GmbH, 35578 Wetzlar, such as the Satisloh 1200-DLX-2.

With the coating unit of type Satisloh 1200-DLX-2, a number of grams of interference layer systems of the disclosure can be produced in one coating run using the method of the disclosure.

Calculation of the number and thicknesses of the layers is a computer-based calculation which takes account of the respective refractive index and of the desired filter effect. To calculate an interference layer system of the disclosure it is possible, for example, to use the software program OptiLayer, version 12.37 from OptiLayer GmbH, 85748 Garching, Munich, or the software program Essential MacLeod version 11.00.541 from Thin Film Center Inc., 2745 E Via Rotunda, Tucson, Ariz. USA.

It has proven very suitable for the high-index transparent optical layer material to be titanium oxide, more particularly TiO₂, and for the low-index transparent optical layer material to be silicon oxide, more particularly SiO₂.

The detached interference layer system, typically an interference layer film, or an interference layer foil, may be comminuted in a suitable medium, as for example in a gas, more particularly air, or in a liquid, as for example in water or an aqueous solution, with input of energy, by stirring or by irradiation of ultrasound, for example, to a desired size or particle size distribution.

The interference layer system of the disclosure may also be introduced directly into a coating material, such as a paint or a varnish, for example, and comminuted to a desired particle size or particle size distribution with stirring or irradiation of ultrasound.

In accordance with the disclosure the interference layer system has a reflection curve which in a wavelength range from 300 nm to 800 nm has at least two regions differing in reflection. These at least two regions differing in reflection have a defined reflection in the respective wavelength range, with the defined reflection of the at least one first reflection region being different from the defined reflection of an at least second reflection region. A defined reflection may have a range of fluctuation in reflection within the respective range of typically 25 percentage points, more typically 20 percentage points, very typically 15 percentage points, and especially typically 10 percentage points, in each case based on the maximum reflection value of the range in question. The maximum reflection value here does not exceed 100% reflection, and the minimum reflection value is not below 0% reflection. In this exemplary embodiment, with particular preference, the interference layer system has a reflection curve which in the wavelength range from 300 nm to 800 nm has at least one region in which the reflection for all wavelengths from a region of at least 70%, typically at least 75%, more typically at least 80% in each case of the full width at half maximum (FWHM) is at least 85%, typically at least 90% and especially typically at least 95%. In the wavelength range from 300 nm to 800 nm, but outside the above-described region, the reflection curve of the interference layer system has at least one region in which the reflection for all wavelengths in this range is typically ≤30%, more typically ≤25%, and especially typically ≤20%. In the wavelength range from 300 nm to 800 nm, but outside the range in which the reflection for all wavelengths from a region of at least 70%, typically at least 75%, more typically at least 80% in each case of the full width at half maximum (FWHM) is at least 85%, typically at least 90%, and especially typically at least 95%, the reflection curve of the interference layer system with particular preference has at least two regions in which the reflection for all wavelengths of this range is typically≤30%, more typically ≤25%, and especially typically ≤20%.

In another preferred exemplary embodiment, the interference layer system has a reflection curve which for any desired wavelength λ₀, typically selected from a wavelength range from 380 nm to 600 nm, including the wavelengths λ₀=380 nm and λ₀=600 nm, in a wavelength range from 300 nm to 800 nm comprises at least one first region having a full width at half maximum (FWHM) calculated in accordance with FWHM=(0.6·λ₀)−170 nm. The relative accuracy for calculation of FWHM above is 10%. In this at least one first region, typically in this exactly one first region, the interference layer system has a reflection curve which in at least one wavelength range of at least 65%, typically at least 70%, more typically at least 75%, in each case of the full width at half maximum (FWHM)=(0.6·λ₀)−170 nm, has a reflection of at least 85%, typically of at least 90%, and especially typically of at least 95%. The information given above is valid for all wavelengths of the at least one first region, i.e., for every wavelength of the at least one first region the reflection curve has a reflection of at least 85%, typically at least 90%, and especially typically of at least 95%. In the case of this other preferred exemplary embodiment, the interference layer system has a reflection curve which for any desired wavelength λ₀, typically selected from a wavelength range from 380 nm to 600 nm, including the wavelengths λ₀₌₃₈₀ nm and λ₀₌₆₀₀ nm, in a wavelength range from 1.1·λ₀ to 800 nm, including 1.1·λ₀ and 800 nm, but outside the at least one first region, comprises at least one second region in which the reflection for all wavelengths of this at least second region is ≤18%, typically ≤15%, and especially typically ≤13%. The arbitrary wavelength λ₀ for the first range is typically to be selected to be identical to the arbitrary wavelength for the second range.

In a further exemplary embodiment, the interference layer system comprises no carrier substrate and at least 4, more typically at least 6, more typically at least 8, very typically at least 10, and especially typically at least 12 layers with different refractive indices that are disposed in alternation over one another. The reflection curve of the interference layer system typically has a reflection, in at least one wavelength range from 365 nm to 425 nm, for each of the stated wavelengths, of typically at least 85%, more typically at least 90%, and very particularly at least 95%. In the above-stated wavelength range, the reflection curve has a full width at half maximum (FWHM) from a range typically from 60 nm to 70 nm. Outside the above-stated wavelength range, in a wavelength range from 440 nm to 800 nm, the reflection curve of the interference layer system has a reflection of typically less than 17%, more typically less than 13%, and especially typically less than 10%.

In the case of another preferred exemplary embodiment, the interference layer system comprises at least 20 layers which are disposed in alternation over one another and which differ in their refractive index. At a wavelength of 550 nm this refractive index difference is typically at least 0.90, more typically at least 0.952. This interference layer system comprising at least 20 layers typically has a reflection, in the region of at least 60%, more typically in the region of at least 65% and especially typically in the region of at least 70% of the full width at half maximum (FWHM), where FWHM=(0.6·λ₀)−170 nm, where λ₀=380 nm to 600 nm, of typically at least 80%, more typically of at least 85%, and especially typically of at least 90%, and has a reflection, typically in the range from 1.1·λ₀ to 800 nm, where λ₀=380 nm to 600 nm, of typically ≤20%, more typically ≤15% and especially typically ≤10%. Typically λ₀ is identical for both ranges defined above. The relative accuracy for the aforesaid calculation of FWHM is 10%. These at least 20 layers typically comprise the optical layer thicknesses below, where T has a refractive index at 550 nm of n=2.420 and L has a refractive index at 550 nm of n=1.468:

| Layer | Optical layer thickness in λ₀/4 |
|---|---|
| 1 | 0.227 T |
| 2 | 1.097 L |
| 3 | 0.661 T |
| 4 | 0.793 L |
| 5 | 1.109 T |
| 6 | 0.668 L |
| 7 | 1.083 T |
| 8 | 0.922 L |
| 9 | 0.810 T |
| 10 | 0.971 L |
| 11 | 1.012 T |
| 12 | 0.708 L |
| 13 | 1.153 T |
| 14 | 1.055 L |
| 15 | 0.611 T |
| 16 | 0.939 L |
| 17 | 1.340 T |
| 18 | 0.263 L |
| 19 | 1.458 T |
| 20 | 1.564 L |

Here λ₀ is a wavelength which may be selected freely, and typically λ₀ is an arbitrary wavelength in the visible spectral range between 380 nm and 780 nm. The statement of the layer thicknesses in multiples of λ₀/4 may be converted as follows into the physical layer thickness d in the unit nm:

$$d = \frac{optical layer thickness \cdot \frac{λ0}{4}}{n} .$$

Here, n is the refractive index of the layer at the wavelength λ₀.

In the case of another preferred exemplary embodiment, the interference layer system comprises at least 22 layers which are disposed in alternation over one another and which differ in their refractive index. At a wavelength of 550 nm this refractive index difference is typically at least 0.90, more typically at least 0.952. The reflection curve of this interference layer system comprising at least 22 layers, typically exactly 22 layers, in the region of at least 62%, more typically in the region of at least 67% and especially typically in the region of at least 72% of the full width at half maximum (FWHM), where FWHM=(0.6·λ₀)−170 nm, where λ₀=380 nm to 600 nm, typically has a reflection of typically at least 82%, more typically of at least 87%, and especially typically of at least 92%, and has a reflection, typically in the range from 1.1·λ₀ to 800 nm, where λ₀=380 nm to 600 nm, of typically ≤18%, more typically ≤15% and especially typically ≤10%. Typically λ₀ is identical for both ranges defined above. The relative accuracy for the aforesaid calculation of FWHM is 10%. These at least 22 layers typically comprise the optical layer thicknesses in accordance with variant A or variant B or variant C below, where T has a refractive index at 550 nm of n=2.420 and L has a refractive index at 550 nm of n=1.468:

| | Variant A, | Variant B, | Variant C, |
|---|---|---|---|
| | optical layer | optical layer | optical layer |
| Layer | thickness in λ₀/4 | thickness in λ₀/4 | thickness in λ₀/4 |
| 1 | 0.227 T | 0.227 T | 0.227 T |
| 2 | 1.097 L | 1.097 L | 1.097 L |
| 3 | 0.661 T | 0.661 T | 0.661 T |
| 4 | 0.793 L | 0.793 L | 0.793 L |
| 5 | 1.109 T | 1.109 T | 1.109 T |
| 6 | 0.668 L | 0.668 L | 0.668 L |
| 7 | 1.083 T | 1.083 T | 1.083 T |
| 8 | 0.922 L | 0.922 L | 0.922 L |
| 9 | 0.818 T | 0.996 T | 1.105 T |
| 10 | 0.967 L | 0.772 L | 0.930 L |
| 11 | 0.810 T | 0.810 T | 0.810 T |
| 12 | 0.971 L | 0.971 L | 0.971 L |
| 13 | 1.012 T | 1.012 T | 1.012 T |
| 14 | 0.708 L | 0.708 L | 0.708 L |
| 15 | 1.153 T | 1.153 T | 1.153 T |
| 16 | 1.055 L | 1.055 L | 1.055 L |
| 17 | 0.611 T | 0.611 T | 0.611 T |
| 18 | 0.939 L | 0.939 L | 0.939 L |
| 19 | 1.340 T | 1.340 T | 1.340 T |
| 20 | 0.263 L | 0.263 L | 0.263 L |
| 21 | 1.458 T | 1.458 T | 1.458 T |
| 22 | 1.564 L | 1.564 L | 1.564 L |

Here λ₀ is a wavelength which may be selected freely, and typically λ₀ is an arbitrary wavelength in the visible spectral range between 380 nm and 780 nm. Conversion into the physical layer thickness takes place as described above.

In the case of another preferred exemplary embodiment, the interference layer system comprises at least 24 layers which are disposed in alternation over one another and which differ in their refractive index. At a wavelength of 550 nm this refractive index difference is typically at least 0.90, more typically at least 0.952. The reflection curve of this interference layer system comprising at least 24 layers, typically exactly 24 layers, in the region of at least 65%, more typically in the region of at least 69% and especially typically in the region of at least 74% of the full width at half maximum (FWHM), where FWHM=(0.6·λ₀)−170 nm, where λ₀=380 nm to 600 nm, typically has a reflection of typically at least 85%, more typically of at least 89%, and especially typically of at least 93%, and has a reflection, typically in the range from 1.1·λ₀ to 800 nm, where λ₀=380 nm to 600 nm, of typically ≤17%, more typically ≤14% and especially typically ≤10%. Typically λ₀ is identical for both ranges defined above. The relative accuracy for the aforesaid calculation of FWHM is 10%. These at least 24 layers typically comprise the optical layer thicknesses in accordance with one of the variants D to L below, where T has a refractive index at 550 nm of n=2.420 and L has a refractive index at 550 nm of n=1.468 and the optical layer thickness is expressed in λ₀/4:

| ¹⁾ | D²⁾ | E | F | G | H | I | J | K | L |
|---|---|---|---|---|---|---|---|---|---|
| 1 | 0.227 T | 0.227 T | 0.227 T | 0.227 T | 0.227 T | 0.227 T | 0.227 T | 0.227 T | 0.227 T |
| 2 | 1.097 L | 1.097 L | 1.097 L | 1.097 L | 1.097 L | 1.097 L | 1.097 L | 1.097 L | 1.097 L |
| 3 | 0.661 T | 0.661 T | 0.661 T | 0.661 T | 0.661 T | 0.661 T | 0.661 T | 0.661 T | 0.661 T |
| 4 | 0.793 L | 0.793 L | 0.793 L | 0.793 L | 0.793 L | 0.793 L | 0.793 L | 0.793 L | 0.793 L |
| 5 | 1.109 T | 1.109 T | 1.109 T | 1.109 T | 1.109 T | 1.109 T | 1.109 T | 1.109 T | 1.109 T |
| 6 | 0.668 L | 0.668 L | 0.668 L | 0.668 L | 0.668 L | 0.668 L | 0.668 L | 0.668 L | 0.668 L |
| 7 | 1.083 T | 1.083 T | 1.083 T | 1.083 T | 1.083 T | 1.083 T | 1.083 T | 1.083 T | 1.083 T |
| 8 | 0.922 L | 0.922 L | 0.922 L | 0.922 L | 0.922 L | 0.922 L | 0.922 L | 0.922 L | 0.922 L |
| 9 | 0.818 T | 0.996 T | 1.105 T | 0.818 T | 0.996 T | 1.105 T | 0.818 T | 0.996 T | 1.105 T |
| 10 | 0.967 L | 0.772 L | 0.930 L | 0.967 L | 0.772 L | 0.930 L | 0.967 L | 0.772 L | 0.930 L |
| 11 | 0.818 T | 0.818 T | 0.818 T | 0.996 T | 0.996 T | 0.996 T | 1.105 T | 1.105 T | 1.105 T |
| 12 | 0.967 L | 0.967 L | 0.967 L | 0.772 L | 0.772 L | 0.772 L | 0.930 L | 0.930 L | 0.930 L |
| 13 | 0.810 T | 0.810 T | 0.810 T | 0.810 T | 0.810 T | 0.810 T | 0.810 T | 0.810 T | 0.810 T |
| 14 | 0.971 L | 0.971 L | 0.971 L | 0.971 L | 0.971 L | 0.971 L | 0.971 L | 0.971 L | 0.971 L |
| 15 | 1.012 T | 1.012 T | 1.012 T | 1.012 T | 1.012 T | 1.012 T | 1.012 T | 1.012 T | 1.012 T |
| 16 | 0.708 L | 0.708 L | 0.708 L | 0.708 L | 0.708 L | 0.708 L | 0.708 L | 0.708 L | 0.708 L |
| 17 | 1.153 T | 1.153 T | 1.153 T | 1.153 T | 1.153 T | 1.153 T | 1.153 T | 1.153 T | 1.153 T |
| 18 | 1.055 L | 1.055 L | 1.055 L | 1.055 L | 1.055 L | 1.055 L | 1.055 L | 1.055 L | 1.055 L |
| 19 | 0.611 T | 0.611 T | 0.611 T | 0.611 T | 0.611 T | 0.611 T | 0.611 T | 0.611 T | 0.611 T |
| 20 | 0.939 L | 0.939 L | 0.939 L | 0.939 L | 0.939 L | 0.939 L | 0.939 L | 0.939 L | 0.939 L |
| 21 | 1.340 T | 1.340 T | 1.340 T | 1.340 T | 1.340 T | 1.340 T | 1.340 T | 1.340 T | 1.340 T |
| 22 | 0.263 L | 0.263 L | 0.263 L | 0.263 L | 0.263 L | 0.263 L | 0.263 L | 0.263 L | 0.263 L |
| 23 | 1.458 T | 1.458 T | 1.458 T | 1.458 T | 1.458 T | 1.458 T | 1.458 T | 1.458 T | 1.458 T |
| 24 | 1.564 L | 1.564 L | 1.564 L | 1.564 L | 1.564 L | 1.564 L | 1.564 L | 1.564 L | 1.564 L |

¹⁾ layer
²⁾variant

In this case as well λ₀ is a wavelength which may be selected freely, and typically λ₀ is an arbitrary wavelength in the visible spectral range between 380 nm and 780 nm. Conversion into the physical layer thickness takes place as described above.

In the case of another preferred exemplary embodiment, the interference layer system comprises at least 26 layers which are disposed in alternation over one another and which differ in their refractive index. At a wavelength of 550 nm this refractive index difference is typically at least 0.90, more typically at least 0.952. The reflection curve of this interference layer system comprising at least 26 layers, typically exactly 26 layers, in the region of at least 70%, more typically in the region of at least 73% and especially typically in the region of at least 75% of the full width at half maximum (FWHM), where FWHM=(0.6·λ₀)−170 nm, where λ₀=380 nm to 600 nm, typically has a reflection of typically at least 87%, more typically of at least 90%, and especially typically of at least 95%, and has a reflection, typically in the range from 1.1·λ₀ to 800 nm, where λ₀=380 nm to 600 nm, of typically ≤16%, more typically ≤13% and especially typically ≤10%. Typically λ₀ is identical for both ranges defined above. The relative accuracy for the aforesaid calculation of FWHM is 10%. These at least 26 layers typically comprise the optical layer thicknesses in accordance with one of the variants M to Z and A′ to M′ below, where T has a refractive index at 550 nm of n=2.420 and L has a refractive index at 550 nm of n=1.468 and the optical layer thickness is expressed in λ₀/4 in three tables below for the variants M to M′:

| ¹⁾ | M²⁾ | N | O | P | Q | R | S | T | U |
|---|---|---|---|---|---|---|---|---|---|
| 1 | 0.227 T | 0.227 T | 0.227 T | 0.227 T | 0.227 T | 0.227 T | 0.227 T | 0.227 T | 0.227 T |
| 2 | 1.097 L | 1.097 L | 1.097 L | 1.097 L | 1.097 L | 1.097 L | 1.097 L | 1.097 L | 1.097 L |
| 3 | 0.661 T | 0.661 T | 0.661 T | 0.661 T | 0.661 T | 0.661 T | 0.661 T | 0.661 T | 0.661 T |
| 4 | 0.793 L | 0.793 L | 0.793 L | 0.793 L | 0.793 L | 0.793 L | 0.793 L | 0.793 L | 0.793 L |
| 5 | 1.109 T | 1.109 T | 1.109 T | 1.109 T | 1.109 T | 1.109 T | 1.109 T | 1.109 T | 1.109 T |
| 6 | 0.668 L | 0.668 L | 0.668 L | 0.668 L | 0.668 L | 0.668 L | 0.668 L | 0.668 L | 0.668 L |
| 7 | 1.083 T | 1.083 T | 1.083 T | 1.083 T | 1.083 T | 1.083 T | 1.083 T | 1.083 T | 1.083 T |
| 8 | 0.922 L | 0.922 L | 0.922 L | 0.922 L | 0.922 L | 0.922 L | 0.922 L | 0.922 L | 0.922 L |
| 9 | 0.818 T | 0.996 T | 1.105 T | 0.818 T | 0.996 T | 1.105 T | 0.818 T | 0.996 T | 1.105 T |
| 10 | 0.967 L | 0.772 L | 0.930 L | 0.967 L | 0.772 L | 0.930 L | 0.967 L | 0.772 L | 0.930 L |
| 11 | 0.818 T | 0.818 T | 0.818 T | 0.996 T | 0.996 T | 0.996 T | 1.105 T | 1.105 T | 1.105 T |
| 12 | 0.967 L | 0.967 L | 0.967 L | 0.772 L | 0.772 L | 0.772 L | 0.930 L | 0.930 L | 0.930 L |
| 13 | 0.818 T | 0.818 T | 0.818 T | 0.818 T | 0.818 T | 0.818 T | 0.818 T | 0.818 T | 0.818 T |
| 14 | 0.967 L | 0.967 L | 0.967 L | 0.967 L | 0.967 L | 0.967 L | 0.967 L | 0.967 L | 0.967 L |
| 15 | 0.810 T | 0.810 T | 0.810 T | 0.810 T | 0.810 T | 0.810 T | 0.810 T | 0.810 T | 0.810 T |
| 16 | 0.971 L | 0.971 L | 0.971 L | 0.971 L | 0.971 L | 0.971 L | 0.971 L | 0.971 L | 0.971 L |
| 17 | 1.012 T | 1.012 T | 1.012 T | 1.012 T | 1.012 T | 1.012 T | 1.012 T | 1.012 T | 1.012 T |
| 18 | 0.708 L | 0.708 L | 0.708 L | 0.708 L | 0.708 L | 0.708 L | 0.708 L | 0.708 L | 0.708 L |
| 19 | 1.153 T | 1.153 T | 1.153 T | 1.153 T | 1.153 T | 1.153 T | 1.153 T | 1.153 T | 1.153 T |
| 20 | 1.055 L | 1.055 L | 1.055 L | 1.055 L | 1.055 L | 1.055 L | 1.055 L | 1.055 L | 1.055 L |
| 21 | 0.611 T | 0.611 T | 0.611 T | 0.611 T | 0.611 T | 0.611 T | 0.611 T | 0.611 T | 0.611 T |
| 22 | 0.939 L | 0.939 L | 0.939 L | 0.939 L | 0.939 L | 0.939 L | 0.939 L | 0.939 L | 0.939 L |
| 23 | 1.340 T | 1.340 T | 1.340 T | 1.340 T | 1.340 T | 1.340 T | 1.340 T | 1.340 T | 1.340 T |
| 24 | 0.263 L | 0.263 L | 0.263 L | 0.263 L | 0.263 L | 0.263 L | 0.263 L | 0.263 L | 0.263 L |
| 25 | 1.458 T | 1.458 T | 1.458 T | 1.458 T | 1.458 T | 1.458 T | 1.458 T | 1.458 T | 1.458 T |
| 26 | 1.564 L | 1.564 L | 1.564 L | 1.564 L | 1.564 L | 1.564 L | 1.564 L | 1.564 L | 1.564 L |

¹⁾ layer
²⁾variant

| ¹⁾ | V²⁾ | W | X | X | Z | A‘ | B‘ | C‘ | D‘ |
|---|---|---|---|---|---|---|---|---|---|
| 1 | 0.227 T | 0.227 T | 0.227 T | 0.227 T | 0.227 T | 0.227 T | 0.227 T | 0.227 T | 0.227 T |
| 2 | 1.097 L | 1.097 L | 1.097 L | 1.097 L | 1.097 L | 1.097 L | 1.097 L | 1.097 L | 1.097 L |
| 3 | 0.661 T | 0.661 T | 0.661 T | 0.661 T | 0.661 T | 0.661 T | 0.661 T | 0.661 T | 0.661 T |
| 4 | 0.793 L | 0.793 L | 0.793 L | 0.793 L | 0.793 L | 0.793 L | 0.793 L | 0.793 L | 0.793 L |
| 5 | 1.109 T | 1.109 T | 1.109 T | 1.109 T | 1.109 T | 1.109 T | 1.109 T | 1.109 T | 1.109 T |
| 6 | 0.668 L | 0.668 L | 0.668 L | 0.668 L | 0.668 L | 0.668 L | 0.668 L | 0.668 L | 0.668 L |
| 7 | 1.083 T | 1.083 T | 1.083 T | 1.083 T | 1.083 T | 1.083 T | 1.083 T | 1.083 T | 1.083 T |
| 8 | 0.922 L | 0.922 L | 0.922 L | 0.922 L | 0.922 L | 0.922 L | 0.922 L | 0.922 L | 0.922 L |
| 9 | 0.818 T | 0.996 T | 1.105 T | 0.818 T | 0.996 T | 1.105 T | 0.818 T | 0.996 T | 1.105 T |
| 10 | 0.967 L | 0.772 L | 0.930 L | 0.967 L | 0.772 L | 0.930 L | 0.967 L | 0.772 L | 0.930 L |
| 11 | 0.818 T | 0.818 T | 0.818 T | 0.996 T | 0.996 T | 0.996 T | 1.105 T | 1.105 T | 1.105 T |
| 12 | 0.967 L | 0.967 L | 0.967 L | 0.772 L | 0.772 L | 0.772 L | 0.930 L | 0.930 L | 0.930 L |
| 13 | 0.996 T | 0.996 T | 0.996 T | 0.996 T | 0.996 T | 0.996 T | 0.996 T | 0.996 T | 0.996 T |
| 14 | 0.772 L | 0.772 L | 0.772 L | 0.772 L | 0.772 L | 0.772 L | 0.772 L | 0.772 L | 0.772 L |
| 15 | 0.810 T | 0.810 T | 0.810 T | 0.810 T | 0.810 T | 0.810 T | 0.810 T | 0.810 T | 0.810 T |
| 16 | 0.971 L | 0.971 L | 0.971 L | 0.971 L | 0.971 L | 0.971 L | 0.971 L | 0.971 L | 0.971 L |
| 17 | 1.012 T | 1.012 T | 1.012 T | 1.012 T | 1.012 T | 1.012 T | 1.012 T | 1.012 T | 1.012 T |
| 18 | 0.708 L | 0.708 L | 0.708 L | 0.708 L | 0.708 L | 0.708 L | 0.708 L | 0.708 L | 0.708 L |
| 19 | 1.153 T | 1.153 T | 1.153 T | 1.153 T | 1.153 T | 1.153 T | 1.153 T | 1.153 T | 1.153 T |
| 20 | 1.055 L | 1.055 L | 1.055 L | 1.055 L | 1.055 L | 1.055 L | 1.055 L | 1.055 L | 1.055 L |
| 21 | 0.611 T | 0.611 T | 0.611 T | 0.611 T | 0.611 T | 0.611 T | 0.611 T | 0.611 T | 0.611 T |
| 22 | 0.939 L | 0.939 L | 0.939 L | 0.939 L | 0.939 L | 0.939 L | 0.939 L | 0.939 L | 0.939 L |
| 23 | 1.340 T | 1.340 T | 1.340 T | 1.340 T | 1.340 T | 1.340 T | 1.340 T | 1.340 T | 1.340 T |
| 24 | 0.263 L | 0.263 L | 0.263 L | 0.263 L | 0.263 L | 0.263 L | 0.263 L | 0.263 L | 0.263 L |
| 25 | 1.458 T | 1.458 T | 1.458 T | 1.458 T | 1.458 T | 1.458 T | 1.458 T | 1.458 T | 1.458 T |
| 26 | 1.564 L | 1.564 L | 1.564 L | 1.564 L | 1.564 L | 1.564 L | 1.564 L | 1.564 L | 1.564 L |

¹⁾ layer
²⁾variant

| ¹⁾ | E‘²⁾ | F‘ | G‘ | H‘ | I‘ | J‘ | K‘ | L‘ | M‘ |
|---|---|---|---|---|---|---|---|---|---|
| 1 | 0.227 T | 0.227 T | 0.227 T | 0.227 T | 0.227 T | 0.227 T | 0.227 T | 0.227 T | 0.227 T |
| 2 | 1.097 L | 1.097 L | 1.097 L | 1.097 L | 1.097 L | 1.097 L | 1.097 L | 1.097 L | 1.097 L |
| 3 | 0.661 T | 0.661 T | 0.661 T | 0.661 T | 0.661 T | 0.661 T | 0.661 T | 0.661 T | 0.661 T |
| 4 | 0.793 L | 0.793 L | 0.793 L | 0.793 L | 0.793 L | 0.793 L | 0.793 L | 0.793 L | 0.793 L |
| 5 | 1.109 T | 1.109 T | 1.109 T | 1.109 T | 1.109 T | 1.109 T | 1.109 T | 1.109 T | 1.109 T |
| 6 | 0.668 L | 0.668 L | 0.668 L | 0.668 L | 0.668 L | 0.668 L | 0.668 L | 0.668 L | 0.668 L |
| 7 | 1.083 T | 1.083 T | 1.083 T | 1.083 T | 1.083 T | 1.083 T | 1.083 T | 1.083 T | 1.083 T |
| 8 | 0.922 L | 0.922 L | 0.922 L | 0.922 L | 0.922 L | 0.922 L | 0.922 L | 0.922 L | 0.922 L |
| 9 | 0.818 T | 0.996 T | 1.105 T | 0.818 T | 0.996 T | 1.105 T | 0.818 T | 0.996 T | 1.105 T |
| 10 | 0.967 L | 0.772 L | 0.930 L | 0.967 L | 0.772 L | 0.930 L | 0.967 L | 0.772 L | 0.930 L |
| 11 | 0.818 T | 0.818 T | 0.818 T | 0.996 T | 0.996 T | 0.996 T | 1.105 T | 1.105 T | 1.105 T |
| 12 | 0.967 L | 0.967 L | 0.967 L | 0.772 L | 0.772 L | 0.772 L | 0.930 L | 0.930 L | 0.930 L |
| 13 | 1.105 T | 1.105 T | 1.105 T | 1.105 T | 1.105 T | 1.105 T | 1.105 T | 1.105 T | 1.105 T |
| 14 | 0.930 L | 0.930 L | 0.930 L | 0.930 L | 0.930 L | 0.930 L | 0.930 L | 0.930 L | 0.930 L |
| 15 | 0.810 T | 0.810 T | 0.810 T | 0.810 T | 0.810 T | 0.810 T | 0.810 T | 0.810 T | 0.810 T |
| 16 | 0.971 L | 0.971 L | 0.971 L | 0.971 L | 0.971 L | 0.971 L | 0.971 L | 0.971 L | 0.971 L |
| 17 | 1.012 T | 1.012 T | 1.012 T | 1.012 T | 1.012 T | 1.012 T | 1.012 T | 1.012 T | 1.012 T |
| 18 | 0.708 L | 0.708 L | 0.708 L | 0.708 L | 0.708 L | 0.708 L | 0.708 L | 0.708 L | 0.708 L |
| 19 | 1.153 T | 1.153 T | 1.153 T | 1.153 T | 1.153 T | 1.153 T | 1.153 T | 1.153 T | 1.153 T |
| 20 | 1.055 L | 1.055 L | 1.055 L | 1.055 L | 1.055 L | 1.055 L | 1.055 L | 1.055 L | 1.055 L |
| 21 | 0.611 T | 0.611 T | 0.611 T | 0.611 T | 0.611 T | 0.611 T | 0.611 T | 0.611 T | 0.611 T |
| 22 | 0.939 L | 0.939 L | 0.939 L | 0.939 L | 0.939 L | 0.939 L | 0.939 L | 0.939 L | 0.939 L |
| 23 | 1.340 T | 1.340 T | 1.340 T | 1.340 T | 1.340 T | 1.340 T | 1.340 T | 1.340 T | 1.340 T |
| 24 | 0.263 L | 0.263 L | 0.263 L | 0.263 L | 0.263 L | 0.263 L | 0.263 L | 0.263 L | 0.263 L |
| 25 | 1.458 T | 1.458 T | 1.458 T | 1.458 T | 1.458 T | 1.458 T | 1.458 T | 1.458 T | 1.458 T |
| 26 | 1.564 L | 1.564 L | 1.564 L | 1.564 L | 1.564 L | 1.564 L | 1.564 L | 1.564 L | 1.564 L |

¹⁾ layer
²⁾variant

As already mentioned above, λ₀, including in each of the three above-recited tables for the variants M to A′, is a wavelength which can be freely selected, with λ₀ typically being an arbitrary wavelength in the visible spectral range between 380 nm and 780 nm. Conversion into the physical layer thickness takes place as described above.

In another exemplary embodiment, each of the interference layer systems described herein has a surface roughness of typically ≤3 nm rms, more typically ≤2 nm rms, and especially typically ≤1 nm rms.

The reflection curves of the interference layer system, described in the exemplary embodiments identified above, are calculated typically using the OptiLayer software program, version 12.37, from OptiLayer GmbH, with reference to the respective interference layer system, i.e., the interference layer system without carrier substrate. It should be emphasized here in particular that the interference layer systems described retain their reflection properties irrespective of the surrounding medium selected. In particular the interference layer systems exhibit the same reflection properties in a range of typically 10 percentage points, more typically in a range of 5 percentage points, of the ranges corresponding to one another, in the following surrounding media (optical entry and exit medium):
air (refractive index at 550 nm n=1.000),
water (refractive index at 550 nm n=1.330),
oily/fatty substances (refractive index at 550 nm n=1.400).

The interference layer systems may therefore be used not only in air but also in aqueous and/or oil-based preparations, without them suffering any loss of or substantial change in their reflection properties.

Alternatively the reflection properties of the interference layer systems may be determined using the F10-AR-UV reflection spectrometer from Filmetrics, Inc., San Diego, Calif. 92121, USA. This determination may be made on the interference layer system with carrier substrate or on the interference layer system without carrier substrate.

Reflection is understood generally to refer to the quotient formed from the reflection intensity IR divided by the total intensity I₀ of the incident radiation, in this case light. The result is reported here in %: Reflection R=I_{R}/I₀·100.

At angles other than 0° for the incidence of the light onto the surface of the interference layer system, effects occur that are referred to as polarization effects; that is, the reflection of nonpolarized light differs in this case from the reflection of light p- or s-polarized with respect to the plane of incidence. Specifically the reflection of the nonpolarized light is the average obtained from the reflection of the p- and s-polarized light. All of the data for reflection in this patent application refer to nonpolarized light in an incident angle range from 0 to 15°. The optical angle of incidence is determined perpendicularly to the surface of the interference layer system. By targeted utilization of the polarization splitting of the reflection between s- and p-polarized light it is also possible, for example, to produce polarization splitters.

The advantage of the interference layer systems described is that the at least one first region of the reflection curve and the at least one second region of the reflection curve, different from the first region, in the wavelength range from 300 nm to 800 nm can be selected variably. The first range and the second range typically have a different reflection over the complete respective range. The first range and the second range are typically adjustable in the wavelength range from 300 nm to 800 nm when the interference layer system is designed. This adjustability ensures an adaptable reflection for different wavelength ranges. Furthermore, the wavelength range can be varied, and so different color ranges can be realized. Where, for example, the reflection curve of the interference layer system comprises at least one, typically exactly one, first region with high reflection and at least one second region with low reflection, the at least one first region with high reflection can be shifted into an arbitrary wavelength range, typically in an arbitrary wavelength range from 300 nm to 800 nm, when the interference layer system is designed.

Another noteworthy advantage of the interference layer system described is that its reflection curve, in a first region of at least 60%, more typically in a first region of at least 65%, very typically in a first region of at least 70%, and especially typically in a first region of at least 75% of the full width at half maximum (FWHM), where FWHM=(0.6·λ₀)−170 nm, where typically λ₀=380 nm to 600 nm, has a reflection of typically at least 80%, more typically at least 85, very typically of at least 90%, and especially typically of at least 95%. This at least one first region, typically this exactly one first region, is adjustable within a wavelength range from typically 300 nm to 800 nm when the interference layer system is designed, allowing the range of high reflection to be selected variably. The relative accuracy for the aforesaid calculation of FWHM is 10%. The reflection curve additionally typically has at least one second range from 1.1·λ₀ to 800 nm, where λ₀=380 nm to 600 nm, in which the reflection is typically 20%, more typically ≤15% and especially typically ≤10%. Depending on the setting of the at least one first region, typically of the exactly one first region, the at least one second region as well is shifted within the wavelength range from typically 300 nm to 800 nm. This setting takes place during design of the interference layer system, through a selection of λ₀, which is selected typically from a range from λ₀=380 nm to 600 nm.

The above-described ranges of different reflection, more particularly the at least one region with high reflection and the at least one region with comparatively low reflection, can be realized with a very small number of layers.

Further exemplary embodiments are provided by the clauses below:

Clause 1: An interference layer system, comprising a plurality of optically transparent layers, where the interference layer system has no carrier substrate and the optically transparent layers are disposed extensively over one another, where the optically transparent layers are selected from the group consisting of dielectrics, metals and combinations thereof, with at least one first optically transparent layer having a refractive index n₁ and at least one second optically transparent layer having a refractive index n₂, and with the first refractive index n₁ and the second refractive index n₂ differing by at least 0.1.

Clause 2: The interference layer system according to clause 1, wherein the layer thickness of each optically transparent layer is in a thickness range from 5 nm to 500 nm.

Clause 3: The interference layer system according to clause 1 or 2, wherein the optically transparent layers each comprise dielectrics, typically metal oxide(s) in an amount of 95 to 100 wt %, based in each case on the total weight of the respective optically transparent layer.

Clause 4: The interference layer system according to one of clauses 1 to 3, wherein the interference layer system has at least 2 low-index optically transparent layers having a refractive index n₁<1.8 and at least 2 high-index optically transparent layers having a refractive index n₂≥1.8.

Clause 5: The interference layer system according to one of clauses 1 to 4, wherein the interference layer system comprises or consists of 4 to 100 optically transparent layers.

Clause 6: The interference layer system according to one of clauses 1 to 5, wherein the low-index optically transparent layer has a refractive index n₁ from a range from 1.3 to 1.78 and is selected typically from the group consisting of silicon oxide, aluminum oxide, magnesium fluoride, and mixtures thereof.

Clause 7: The interference layer system according to one of clauses 1 to 6, wherein the high-index optically transparent layer has a refractive index n₂ from a range from 2.0 to 2.9 and is selected typically from the group consisting of titanium oxide, iron oxide, niobium oxide, tantalum oxide, zirconium oxide, chromium oxide, cerium oxide, cobalt oxide, and mixtures thereof.

Clause 8: The interference layer system according to one of clauses 1 to 7, wherein each optical transparent layer consists exclusively of one metal oxide.

Clause 9: The interference layer system according to one of clauses 1 to 8, wherein the low-index and high-index optical transparent layers are disposed in alternation over one another and typically bordering one another.

Clause 10: The interference layer system according to one of clauses 1 to 9, wherein the interference layer system is a foil, a film or a particle.

Clause 11: A method for producing an interference layer system according to one of clauses 1 to 10, the method comprising the following steps:
(a) providing an extensive carrier substrate material,
(b) applying a release layer,
(c) applying a plurality of optically transparent layers, to generate an interference layer system,
(d) detaching the interference layer system from the extensive carrier substrate material.

Clause 12: The method according to clause 11, wherein the optically transparent layers are applied by vapor deposition.

Clause 13: The method according to clause 11 or 12, the release layer is formed from a water-soluble inorganic salt.

Clause 14: An optical filter, wherein the optical filter is or comprises an interference layer system according to one of clauses 1 to 10.

Clause 15: An application medium, wherein the application medium comprises an interference layer system according to one of clauses 1 to 10.

The disclosure is illustrated more closely below with reference to examples and figures, though without being limited thereto.

### BRIEF DESCRIPTION OF THE DRAWINGS

The disclosure will now be described with reference to the drawings wherein:

FIG. 1 shows a calculated reflection curve of an interference layer system of the disclosure composed of a total of 26 layers of TiO₂ and SiO₂ disposed in alternation;

FIG. 2 shows the interference layer film of the disclosure or an interference layer foil of the disclosure, for which the reflection curve from FIG. 1 was calculated and measured, on a scanning electron microscope slide;

FIG. 3 shows an SEM micrograph (SEM: scanning electron microscope) of the interference layer film of the disclosure for which the reflection curve from FIG. 1 was calculated and measured, and which can be seen in FIG. 2; and

FIG. 4 shows the reduction in the transmission in the wavelength range between 350 nm and 800 nm when using an interference layer system for which the reflection curve from FIG. 1 was calculated and measured and which can be seen in FIG. 2 and FIG. 3, respectively.

### DESCRIPTION OF EXEMPLARY EMBODIMENTS

An extensive substrate material in the form of a plastic substrate coated with a polysiloxane-based hardcoat material MP-1154D (SDC TECHNOLOGIES, INC.) was disposed as carrier substrate material in accordance with manufacturer data in a Satisloh 1200-DLF coating unit.

The plastic substrate material was an uncoated spectacle lens made of CR39 polymer and having a circular diameter of 6.5 cm and a thickness in the middle of 1.5 mm. First of all the primer PR-1156 (SDC TECHNOLOGIES, INC.) had been applied by dip-coating in a layer thickness of 750 nm to the plastic substrate material. Drying took place for 5 min at a temperature of 70° C. in a ULE 600 vertical oven from Memmert GmbH+Co. KG, D-91126 Schwabach. The polysiloxane-based hardcoat material MP-1154D had been subsequently applied in a layer thickness of 2500 nm by dip coating. Drying and curing then took place for 120 min at a temperature of 110° C. in a ULE 600 vertical oven from Memmert GmbH+Co. KG D-91126 Schwabach.

Before the actual deposition of the layer materials commenced, the surface was bombarded with ions in vacuum at a pressure of less than 8×10⁻⁴ mbar. The ions came from an End-Hall-type ion source. This ion source is part of the coating unit. The ions were Ar ions with an energy of between 80 eV and 130 eV. The ion current density reaching the substrates was between 20 and 60 μA/cm². Bombardment with Ar ions took place for 2 minutes.

After the end of Ar ion bombardment, a layer of NaCl 30 nm thick was first applied in a high vacuum without reactive gas to the hardcoated plastic substrate material, using the electron beam evaporator in the Satisloh coating unit, at a pressure of 4×10⁻⁴ mbar and a deposition rate of 0.2 nm/s. Subsequently a total of 26 layers of TiO₂ and SiO₂ were applied in vacuum under a pressure of 4×10⁻⁴ mbar. During the coating of the TiO₂ layers, oxygen was added as reactive gas (20 sccm), so that the layers grew without absorption in the visible spectral range and were therefore optically transparent. During the deposition of the TiO₂, the substrate was also bombarded with ions. These ions came from an End-Hall-type ion source. This ion source is part of the coating unit. The ions were oxygen ions with an energy of between 80 eV and 130 eV. The ion current density reaching the substrates was between 20 and 60 μA/cm². The bombardment of the growing TiO₂ layer with oxygen ions, like the addition of reactive gas, was a contributing factor to the growth of the TiO₂ layers in the form of an optically transparent layer. Here, layers of TiO₂ and layers of SiO₂ were applied in alternation. The first metal oxide layer applied directly to the NaCl release layer was a TiO₂ layer. The respectively applied layer thickness of the TiO₂ layer and SiO₂ layer is reported in [nm] in Table 2.

TABLE 2

| | | t/nm |
|---|---|---|
| Substrate | CR39 | |
| Primer | PR-1156 | 750 |
| Hardcoat | MP-1154D | 2500 |
| Release layer | NaCl | 30 |
| 1 | TiO₂ | 8.6 |
| 2 | SiO₂ | 73.2 |
| 3 | TiO₂ | 25.1 |
| 4 | SiO₂ | 52.9 |
| 5 | TiO₂ | 42.1 |
| 6 | SiO₂ | 44.5 |
| 7 | TiO₂ | 41.1 |
| 8 | SiO₂ | 61.5 |
| 9 | TiO₂ | 31.0 |
| 10 | SiO₂ | 64.5 |
| 11 | TiO₂ | 37.8 |
| 12 | SiO₂ | 51.5 |
| 13 | TiO₂ | 41.9 |
| 14 | SiO₂ | 62.0 |
| 15 | TiO₂ | 30.7 |
| 16 | SiO₂ | 64.7 |
| 17 | TiO₂ | 38.4 |
| 18 | SiO₂ | 47.2 |
| 19 | TiO₂ | 43.7 |
| 20 | SiO₂ | 70.4 |
| 21 | TiO₂ | 23.2 |
| 22 | SiO₂ | 62.6 |
| 23 | TiO₂ | 50.8 |
| 24 | SiO₂ | 17.5 |
| 25 | TiO₂ | 55.3 |
| 26 | SiO₂ | 104.3 |

t/nm: Thickness in [nm]

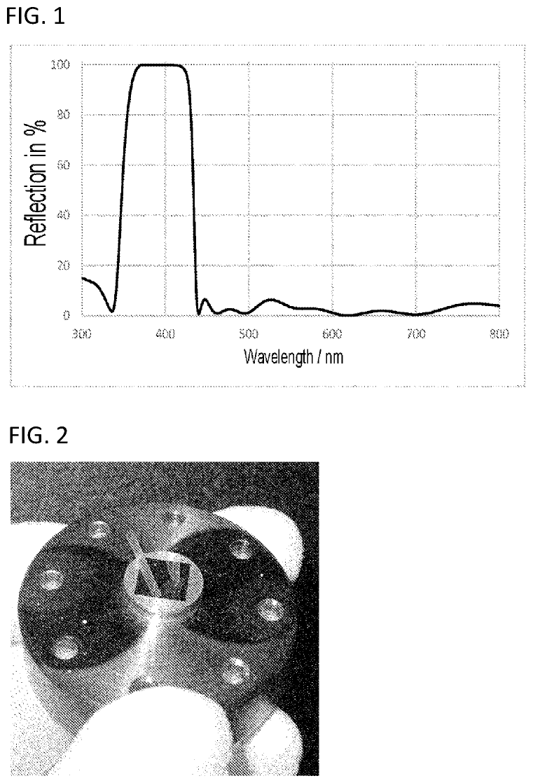

The respective layer thickness was set via the duration of vapor deposition, in accordance with manufacturer details relating to the coating unit. The layer thickness here was determined using a quartz crystal oscillator system (XTC Controller, Inficon, CH-7310 Bad Ragaz) which measures the change in the frequency of an electrical crystal oscillator, the frequency changing with the layer thickness of the growing interference layer system. The crystal oscillator is coated onto the plastic carrier substrate during the coating procedure, in an analogous way, and the change in frequency thereof is measured at the same time. The reflection curve calculated for the interference layer system with a total of 26 layers (see Table 2) is shown in FIG. 1.

A measurement was carried out in order to monitor the applied coating: the reflection curve was measured using the F10-AR-UV reflection spectrometer from Filmetrics, Inc. (San Diego, Calif. 92121, USA), with the measurement head, after calibration of the instrument according to manufacturer instructions, being placed onto a coated region of the plastic carrier substrate directly after production of the interference layer system. This measurement was made within 5 minutes after admission of air to the vacuum coating unit, when coating had been ended. The reflection curve was measured on the interference layer film still adhering to the plastic carrier substrate, since it is complicated to measure a reflection curve on an interference layer film detached from the plastic carrier substrate.

The layer thicknesses applied in each case were calculated using the OptiLayer software program, version 12.37, from OptiLayer GmbH. For the purposes of calculation of the target reflection curve, a factor taken into account was that the interference layer system of the disclosure, during the measurement as well, was disposed over the release layer, hardcoat layer and primer coat on the carrier substrate material. For the calculation, therefore, a target reflection curve was input initially. The software program possessed algorithms which calculate interference layer systems, taking boundary conditions into account. The algorithm selected for the calculation was “gradual evolution.” The boundary conditions stipulated were the substrate material, the primer coat with its optical properties and layer thickness, the hardcoat layer with its optical properties and layer thickness, the release layer of NaCl with its optical properties and layer thickness, and the use of TiO₂ and SiO₂ as layer materials. The maximum number of layers was limited to 26. The algorithm optimized the number of layers and their thickness until a minimum deviation relative to the target curve was achieved. A result of this optimization were the layer thicknesses reported in Table 2. The results of the measured reflection curve agreed with the calculated target reflection curve. Accordingly, the interference layer system detached from the carrier substrate also had the calculated/measured reflection curve.

After the end of the coating operation, the coated substrates were removed from the coating unit and left to stand in the laboratory at room temperature for 5 hours. The relative atmospheric humidity in the laboratory was more than 30%. The interference layer film or interference layer foil was then removed from the substrate surface using tweezers. As a result of intrinsic stresses, the interference layer film or interference layer foil rolled itself up, as shown in FIG. 2.

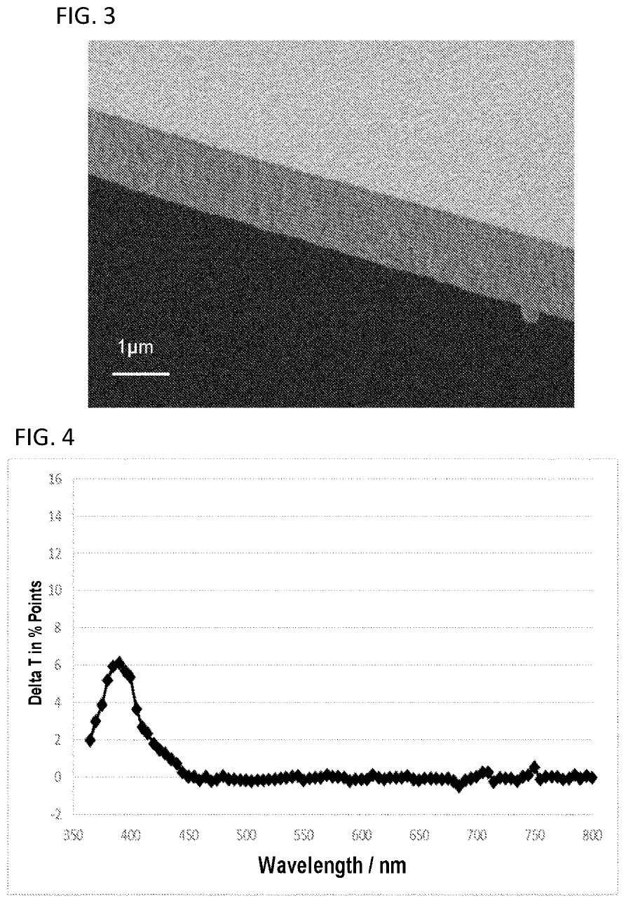

FIG. 3 shows an SEM micrograph (SEM: scanning electron microscope) of the interference layer film of the disclosure. The individual layers of TiO₂ and SiO₂ are clearly perceptible. In order to determine the effect in a coating material of relatively high viscosity, approximately 1% by mass of the detached interference layer film was incorporated into glycerol with stirring. The stirring produced comminution of the interference layer film, to give interference layer particles. A film of the interference layer particle-containing glycerol was then applied to a slide in a layer thickness of 50 μm, and the spectral transmission in the wavelength range from 350 nm to 1050 nm was measured using an Ultrascan Spectrophotometer from Hunter Associates Laboratory, Inc. 11491 Sunset Hills Road, Reston, Va. 20190-5280, USA. In order to calculate the contribution of the interference layer particles alone, a glycerol film without interference layer particles was subjected to measurement beforehand.

In FIG. 4, the change in transmission, delta T, resulting from the addition of the interference layer particles is plotted. This was calculated as the difference between the transmission curves with and without interference layer particles in glycerol.

From FIG. 4 it is apparent that the addition of the interference layer particles of the disclosure resulted in a significant reduction in transmission within a wavelength range <430 nm, whereas the transmission at longer wavelengths was not affected.

The average particle size of the interference layer particles of the disclosure in glycerol, with glycerol being used as a model of a viscous coating system, was determined under an optical microscope and found to be about 40 μm.

When the concentration of the interference layer particles in glycerol was increased, a further reduction in the transmission was possible.

The foregoing description of the exemplary embodiments of the disclosure illustrates and describes the present invention. Additionally, the disclosure shows and describes only the exemplary embodiments but, as mentioned above, it is to be understood that the disclosure is capable of use in various other combinations, modifications, and environments and is capable of changes or modifications within the scope of the concept as expressed herein, commensurate with the above teachings and/or the skill or knowledge of the relevant art.

The term “comprising” (and its grammatical variations) as used herein is used in the inclusive sense of “having” or “including” and not in the exclusive sense of “consisting only of.” The terms “a” and “the” as used herein are understood to encompass the plural as well as the singular.

All publications, patents and patent applications cited in this specification are herein incorporated by reference, and for any and all purposes, as if each individual publication, patent or patent application were specifically and individually indicated to be incorporated by reference. In the case of inconsistencies, the present disclosure will prevail.

1. An interference layer system, comprising:
a plurality of optically transparent layers having no carrier substrate, the optically transparent layers being disposed extensively over one another,
wherein the optically transparent layers are selected from the group consisting of dielectrics, with at least one first optically transparent layer having a refractive index n₁ and at least one second optically transparent layer having a refractive index n₂, and with the first refractive index n₁ and a second refractive index n₂ differing by at least 0.1,
wherein a reflection curve of the interference layer system in a wavelength range from 300 nm to 800 nm has at least two regions of different reflection,
wherein the interference layer system contains no purely metallic layers and no layers containing elemental metal,
wherein an overall thickness of the interference layer system is from 40 nm to 5 μm,
wherein the reflection curve of the interference layer system has a reflection of at least 70% at least in a first region of at least 60% of a full width at half maximum (FWHM),
wherein FWHM=(0.6·λ₀)−170 nm, with λ₀=380 nm to 600 nm,
wherein a calculation of the FWHM has a relative error of 10%,
wherein the reflection curve of the interference layer system is determined for nonpolarized light in an incident angle range from 0° to 15°, and
wherein the reflection curve of the interference layer system has a reflection of ≤20% at least in a second range from ≥1.1·λ₀ to ≤800 nm.

2. The interference layer system as claimed in claim 1, wherein a layer thickness of each optically transparent layer is in a range from 5 nm to 500 nm.

3. The interference layer system as claimed in claim 1, wherein the optically transparent layers each contain a metal oxide in an amount of 95 to 100 wt %, based in each case on a total weight of the respective optically transparent layer.

4. The interference layer system as claimed in claim 1, wherein the interference layer system has at least 2 low-index optically transparent layers having the refractive index n₁<1.8 and at least 2 high-index optically transparent layers having the refractive index n₂≥1.8.

5. The interference layer system as claimed in claim 1, wherein the interference layer system comprises or consists of 4 to 100 optically transparent layers.

6. The interference layer system as claimed in claim 1, wherein a low-index optically transparent layer has the refractive index n₁ in a range from 1.3 to 1.78, and
wherein the low-index optically transparent layer is selected from the group consisting of silicon oxide, aluminum oxide, magnesium fluoride, and mixtures thereof.

7. The interference layer system as claimed in claim 1, wherein a high-index optically transparent layer has the refractive index n₂ in a range from 2.0 to 2.9, and
wherein the high-index optically transparent layer is selected from the group consisting of titanium oxide, iron oxide, niobium oxide, tantalum oxide, zirconium oxide, chromium oxide, cerium oxide, cobalt oxide, and mixtures thereof.

8. The interference layer system as claimed in claim 1, wherein each optically transparent layer consists of a metal oxide.

9. The interference layer system as claimed in claim 1, wherein the interference layer system comprises at least 20 optically transparent layers, and wherein a refractive index difference between two adjacent optically transparent layers is at least 0.90.

10. The interference layer system as claimed in claim 1, wherein the interference layer system has a same reflection property in a range of up to 10 percentage points of the regions corresponding to one another in the following optical entry and exit media:
air with a refractive index at 550 nm of n=1.000; or
water with a refractive index at 550 nm of n=1.330; or
oily/fatty substances with a refractive index at 550 nm of n=1.400.

11. A method for producing an interference layer system as claimed in claim 1, the method comprising:
providing an extensive carrier substrate material;
applying a release layer;
applying a plurality of optically transparent layers to generate the interference layer system; and
detaching the interference layer system from the extensive carrier substrate material.

12. The method as claimed in claim 11, further comprising:
applying the optically transparent layers by vapor deposition.

13. The method as claimed in claim 11, further comprising:
forming the release layer from a water-soluble inorganic salt.

14. An optical filter, wherein the optical filter is or comprises the interference layer system as claimed in claim 1.

15. An application medium comprising:
the interference layer system as claimed in claim 1.

16. An interference layer system comprising:
at least 20 optically transparent layers disposed in alternation over one another and having respectively different refractive indices,
wherein a reflection curve of the interference layer system in a wavelength range of 300 nm and 800 nm has at least two regions of different reflection, and at least one wavelength range of these at least two wavelength ranges has a reflection of at least 70% in a region of at least 60% of the full width at half maximum (FWHM), where FWHM=(0.6·λ₀)−170 nm,
wherein λ₀=380 nm to 600 nm,
wherein the reflection curve of the interference layer system is determined for nonpolarized light in an incident angle range from 0 to 15°,
wherein the interference layer system contains no purely metallic layers and/or layers containing elemental metal, and
wherein an overall thickness of the interference layer system is from 40 nm to 5 μm, and
wherein at least one region, which is different from the at least one wavelength range of these at least two wavelength ranges, has a reflection of ≤20% in a range from ≥1.1·λ₀ to ≤800 nm.

17. The interference layer system as claimed in claim 16, wherein exactly one wavelength region of the at least two wavelength regions has a reflection of at least 70% in a region of at least 60% of the FWHM.

18. The interference layer system as claimed in claim 16, wherein a refractive index difference between two adjacent optically transparent layers is at least 0.90.

19. The interference layer system as claimed in claim 16, wherein the interference layer system has a surface roughness of ≤3 nm rms.

20. The interference layer system as claimed in claim 16, wherein the interference layer system has a layer sequence 0.227 T/1.097 L/0.661 T/0.793 L/1.109 T/0.668 L/1.083 T/0.922 L/0.810 T/0.971 L/1.012 T/0.708 L/1.153 T/1.055 L/0.611 T/0.939 L/1.340 T/0.263 L/1.458 T/1.564 L, with the optical layer thicknesses in λ₀/4, with a refractive index for Tat 550 nm of n=2.420, and a refractive index for L at 550 nm of n=1.468.
